(19) United States
(12) Patent Application Publication
(10) Pub. No.: US 2026/0123392 A1
(43) Pub. Date: Apr. 30, 2026

(54) INTERCONNECT STRUCTURE INCLUDING ANISOTROPIC TRANSPORT MATERIAL AND METHOD FOR MANUFACTURING THE SAME

(71) Applicant: TAIWAN SEMICONDUCTOR MANUFACTURING COMPANY, LTD., Hsinchu (TW)

(72) Inventors: Cian-Yu CHEN, Hsinchu (TW); Meng-Pei LU, Hsinchu (TW); Shin-Yi YANG, Hsinchu (TW)

(73) Assignee: TAIWAN SEMICONDUCTOR MANUFACTURING COMPANY, LTD., Hsinchu (TW)

(21) Appl. No.: 18/928,838

(22) Filed: Oct. 28, 2024

(51) Int. Cl. H01L 23/528; H01L 21/768; H01L 23/532

(52) U.S. Cl. CPC H10W 20/435; H10W 20/056; H10W 20/427; H10W 20/4435; H10W 20/4446; H10W 20/4462

(57) ABSTRACT

A semiconductor device includes a substrate, and an interconnect structure disposed over the substrate. The interconnect structure includes a first conductive interconnect serving as a contact via, and a second conductive interconnect connected to the first conductive interconnect and serving a metal line. The second conductive interconnect includes a plurality of anisotropic transport material films extending in a lengthwise direction of the second conductive interconnect.

### BACKGROUND

The semiconductor integrated circuit (IC) industry has experienced tremendous advancements over the past decades and is still experiencing vigorous development. With the dramatic advances in IC design, new generations of ICs have small and complex circuits. A damascene process (for example, a single damascene process or a dual damascene process) is one of the techniques used for forming back-end-of-line (BEOL) interconnect structures. The interconnect structures play an important role in miniaturization and electrical performance of the new generations of ICs. Thus, the industry pays much attention to the development of the interconnect structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 12 are schematic views illustrating some stages of the method as depicted in FIG. 1 in accordance with some embodiments.

FIGS. 13 and 14 are schematic views each illustrating a semiconductor device in accordance with some embodiments.

FIG. 15 is a flow diagram illustrating a method for manufacturing a semiconductor device in accordance with some embodiments.

FIGS. 16 to 23 are schematic views illustrating some stages of the method as depicted in FIG. 15 in accordance with some embodiments.

FIGS. 24 to 57 are schematic views each illustrating a semiconductor device in accordance with some embodiments.

FIG. 58 is a flow diagram illustrating a method for manufacturing a semiconductor device in accordance with some embodiments.

FIGS. 59 to 63 are schematic views illustrating some stages of the method as depicted in FIG. 58 in accordance with some embodiments.

FIGS. 64 and 65 are schematic views each illustrating a semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “upwardly,” “downwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

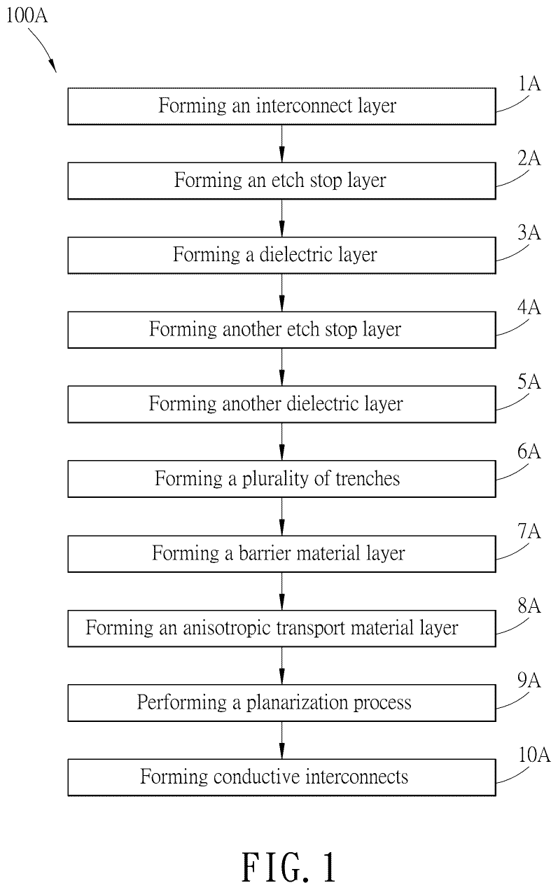

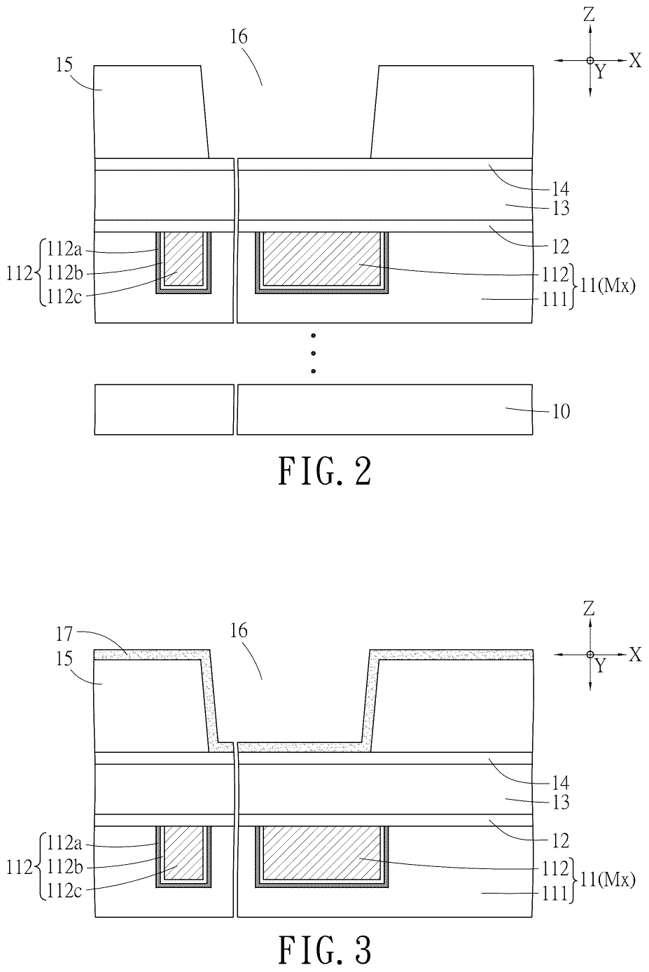

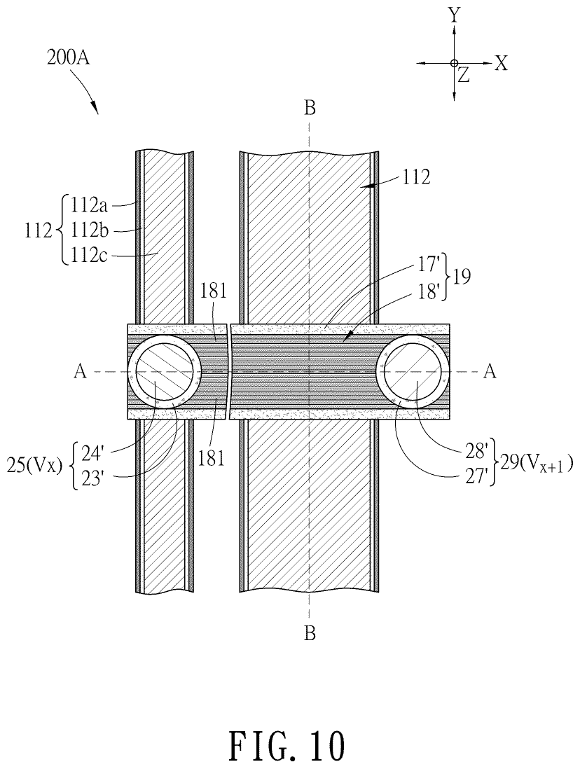

The present disclosure is directed to a semiconductor device including an interconnect structure in which resistance between two adjacent interconnect layers of the interconnect structure is reduced by using an anisotropic transport material for forming conductive interconnects of at least one of the two adjacent interconnect layers. The present disclosure is also directed to a method for manufacturing the semiconductor device. FIG. 1 is a flow diagram illustrating a method 100A for manufacturing a semiconductor device (for example, a semiconductor device 200A shown in FIGS. 10 to 12) in accordance with some embodiments. FIGS. 2 to 9 illustrate schematic views of some intermediate stages of the method 100A. Some portions may be omitted in FIGS. 2 to 12 for the sake of brevity. Additional steps can be provided before, after or during the method 100A, and some of the steps described herein may be replaced by other steps or be eliminated.

Referring to FIG. 1 and the example illustrated in FIG. 2, the method 100A begins at step 1A, where an interconnect layer 11 is formed over a substrate 10 in a Z direction normal to the substrate 10.

In some embodiments, the substrate 10 is a semiconductor substrate, which may include, for example, but not limited to, an elemental semiconductor or a compound semiconductor. The elemental semiconductor includes a single species of atoms, such as silicon or germanium in column XIV of a periodic table, and may be in a crystal form, a polycrystalline form, or an amorphous form. Other suitable elemental semiconductor materials are within the contemplated scope of the present disclosure. The compound semiconductor includes two or more elements, and examples thereof may include, but not limited to, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate may include a multilayer compound semiconductor substrate. In some embodiments, the semiconductor substrate may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable materials are within the contemplated scope of the present disclosure. The SOI substrate may be doped with a P-type dopant, for example, but not limited to, boron, aluminum, or gallium. Other suitable P-type dopant materials are within the contemplated scope of the present disclosure. Alternatively, the SOI substrate may be doped with an N-type dopant, for example, but not limited to, nitrogen, phosphorus, or arsenic. Other suitable N-type dopant materials are within the contemplated scope of the present disclosure. In some embodiments, the semiconductor substrate may further include various active regions, for example, the active regions configured for an N-type metal oxide semiconductor transistor device (NMOS) or the active regions configured for a P-type metal oxide semiconductor transistor device (PMOS).

In some embodiments, the interconnect layer 11 serves as a metal line layer (Mₓ), and includes a dielectric layer (i.e., an inter-metal dielectric layer) 111 and a plurality of conductive interconnects (for example, metal lines) 112 disposed in the dielectric layer 111 and separated from one another. In some embodiments, the conductive interconnects 112 extend in a Y direction transverse to the Z direction and parallel to the substrate 10. In some embodiments, the Y direction is perpendicular to the Z direction. In some embodiments, the dielectric layer 111 may include, for example, but not limited to, silicon oxide, silicon nitride, silicon carbide, silicon oxycarbide, silicon oxycarbide doped with hydrogen, silicon oxynitride, or other low dielectric constant (low-k) dielectric materials. Other suitable dielectric materials are within the contemplated scope of the present disclosure. In some embodiments, the dielectric layer 111 has a dielectric constant (k) value ranging from about 1 to about 5. In some embodiments, each of the conductive interconnects 112 serving as the metal lines has a dimension ranging from about 1 nanometer (nm) to about 250 nm, and includes a barrier layer 112a, a liner layer 112b disposed on the barrier layer 112a, and a conductive bulk region 112c disposed on the liner layer 112b and separated from the barrier layer 112a by the liner layer 112b. The barrier layer 112a and the liner layer 112b are formed separately and sequentially. In some embodiments, the barrier layer 112a may include, for example, but not limited to, tantalum, zinc, manganese, zirconium, titanium, hafnium, niobium, vanadium, chromium, scandium, yttrium, silicon, tungsten, molybdenum, aluminum, or combinations thereof. Other suitable materials are within the contemplated scope of the present disclosure. In some embodiments, the liner layer 112b may include, for example, but not limited to, cobalt, ruthenium, tantalum, or combinations thereof. Other suitable materials are within the contemplated scope of the present disclosure. In some embodiments, the conductive bulk region 112c includes copper, aluminum, ruthenium, tungsten, cobalt, molybdenum, tantalum, iron, nickel, rhodium, platinum, palladium, iridium, osmium, rhenium, silver, gold, or combinations thereof. Other suitable materials are within the contemplated scope of the present disclosure.

In some embodiments, the interconnect layer 11 may be formed using a single damascene processes. In the single damascene process, the dielectric layer 111 is formed over the substrate 10 by a suitable deposition process as is known in the art of semiconductor fabrication, for example, but not limited to, an atomic layer deposition (ALD) process, a chemical vapor deposition (CVD) process, a plasma-enhanced ALD (PEALD) process, a plasma-enhanced CVD (PECVD) process, or a physical vapor deposition (PVD) process. Other suitable deposition techniques are within the contemplated scope of the present disclosure. A plurality of trenches (not shown) are formed in the dielectric layer 111 by patterning the dielectric layer 111 using a suitable etching process (for example, but not limited to, a dry etching process or a wet etching process) through an opening pattern formed in a patterned mask layer (not shown) disposed on the dielectric layer 111. In some embodiments, each of the trenches has a dimension ranging from about 1 nm to about 250 nm. A barrier material layer for forming the barrier layer 112a is conformally deposited on the dielectric layer 111 formed with the trenches, a liner material layer for forming the liner layer 112b is then conformally deposited on the barrier material layer, and a conductive metal layer for forming the conductive bulk region 112c is formed on the liner material layer to fill the trenches. In some embodiments, each of the barrier material layer, the liner material layer, and the conducive metal layer may be formed independently by a suitable deposition process as is known in the art of semiconductor fabrication, such as electrochemical plating (ECP), electroless deposition (ELD), PVD, CVD, ALD, PEALD, PECVD, or combinations thereof. Other suitable deposition techniques are within the contemplated scope of the present disclosure. Excess of the barrier material layer, excess of the liner material layer, and excess of the conductive metal layer over the dielectric layer 111 are removed by a planarization process (for example, but not limited to, a chemical mechanical planarization (CMP) process) to form the conductive interconnects 112. In some embodiments, the deposition process for forming each of the barrier material layer, the liner material layer, and the conductive metal layer may be conducted at a temperature ranging from about 25° C. to about 1000° C.

Referring to FIG. 1 and the example illustrated in FIG. 2, the method 100A proceeds to step 2A, where an etch stop layer 12 is formed on the interconnect layer 11. In some embodiments, the etch stop layer 12 may include silicon nitride, silicon nitride doped with carbon, silicon oxide, silicon oxynitride, silicon oxynitride doped with carbon, silicon carbide, silicon oxycarbide, metal nitride (for example, but not limited to, titanium nitride or aluminum nitride), metal oxide (for example, but not limited to, aluminum oxide), metal carbide (for example, but not limited to, tungsten carbide), or combinations thereof. Other suitable materials are within the contemplated scope of the present disclosure. The etch stop layer 12 may be a single-layer configuration, a bi-layered configuration, or a multi-layered configuration. In some embodiments, the etch stop layers 12 may be formed by a suitable deposition process as is known in the art of semiconductor fabrication, for example, but not limited to, PVD, CVD, ALD, PEALD, or PECVD. Other suitable deposition techniques are within the contemplated scope of the present disclosure.

Referring to FIG. 1 and the example illustrated in FIG. 2, the method 100A proceeds to step 3A, where a dielectric layer 13 is formed on the etch stop layer 12 opposite to the interconnect layer 11. The material and the process for forming the dielectric layer 13 may be the same as or similar to those for forming the dielectric layer 111 described above in step 1A, and details thereof are omitted for the sake of brevity.

Referring to FIG. 1 and the example illustrated in FIG. 2, the method 100A proceeds to step 4A, where an etch stop layer 14 is formed on the dielectric layer 13 opposite to the etch stop layer 12. The material and the process for forming the etch stop layer 14 may be the same as or similar to those for forming the etch stop layer 12 described above in step 2A, and details thereof are omitted for the sake of brevity.

Referring to FIG. 1 and the example illustrated in FIG. 2, the method 100A proceeds to step 5A, where a dielectric layer 15 is formed on the etch stop layer 14 opposite to the dielectric layer 13. The material and the process for forming the dielectric layer 15 may be the same as or similar to those for forming the dielectric layer 111 described above in step 1A, and details thereof are omitted for the sake of brevity.

Referring to FIG. 1 and the example illustrated in FIG. 2, the method 100A proceeds to step 6A, where a plurality of trenches 16 are formed in the dielectric layer 15. In some embodiment, the trenches 16 extend in an X direction transverse to the Y direction and the Z direction, and are spaced apart from one another in the Y direction. In some embodiments, the X direction is perpendicular to the Y direction and the Z direction. The process for forming the trenches 16 is the same as or similar to that for forming the trenches described above in step 1A, and details thereof are omitted for the sake of brevity.

Referring to FIG. 1 and the example illustrated in FIG. 3, the method 100A proceeds to step 7A, where a barrier material layer 17 is formed on the structure shown in FIG. 2. The material and the process for forming the barrier material layer 17 may be the same as or similar to those for forming the barrier layer 112a (or the barrier material layer) described above in step 1A, and details thereof are omitted for the sake of brevity.

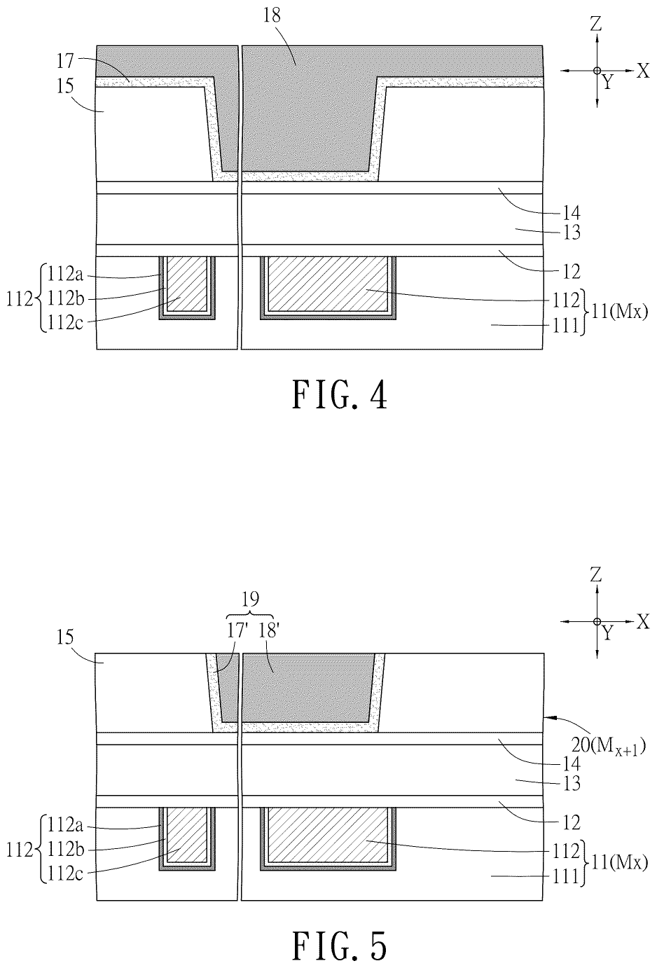

Referring to FIG. 1 and the example illustrated in FIG. 4, the method 100A proceeds to step 8A, where an anisotropic transport material layer 18 is formed on the barrier material layer 17 to fill the trenches 16 (see FIG. 3). In some embodiments, the anisotropic transport material layer 18 may include a two-dimensional (2D) metallic delafossite compound, a MAX-phase composition, a MXene composition, a metal alloy or an intermetallic compound possessing an anisotropic crystal structure, graphene, or combinations thereof. The 2D metallic delafossite compound possesses a highly anisotropic crystal structure. In some embodiments, the 2D metallic delafossite compound has a formula of ABO₂, wherein A and B are different from each other and each of A and B is, for example, but not limited to, palladium, platinum, cobalt, chromium, or rhodium. Other suitable 2D metallic delafossite compounds are within the contemplated scope of the present disclosure. In some embodiments, two or more of the 2D metallic delafossite compounds may be used together in any compositions. In some embodiments, the MAX-phase composition has a formula of Mₙ₊₁AXₙ, wherein M is an early transition metal (for example, but not limited to, scandium, titanium, vanadium, chromium, zirconium, niobium, molybdenum, hafnium, or tantalum); A is an element in column IIIA or IVA of the periodic table (for example, but not limited to, zinc, cadmium, aluminum, gallium, indium, titanium, silicon, germanium, tin, lead, phosphorus, arsenic, or sulfur); X is carbon or nitrogen; and n is an integer ranging from about 1 to about 4. Other suitable MAX-phase compositions are within the contemplated scope of the present disclosure. In some embodiments, the MXene composition is a 2D transition metal carbide or nitride having a formula of Mₙ₊₁XₙTₓ, wherein M is scandium, titanium, vanadium, chromium, manganese, yttrium, zirconium, niobium, molybdenum, hafnium, tantalum, or tungsten; X is carbon or nitride; Tₓ is a surface termination (for example, but not limited to, a hydrogen radical, an oxygen radical, a hydroxyl radical, a chlorine radical, a fluorine radical, a bromine radical, an iodine radical, a sulfur radical, a selenium radical, a tellurium radical, or combinations thereof); and n is an integer ranging from about 1 to about 4. Other suitable MXene compositions are within the contemplated scope of the present disclosure. In some embodiments, the metal alloy or the intermetallic compound possessing an anisotropic crystal structure includes two or more selected from transition metals or semi-metals. In some embodiments, the metal alloy or the intermetallic compound possessing an anisotropic crystal structure includes two or more selected from scandium, titanium, vanadium, chromium, manganese, iron, cobalt, copper, zinc, yttrium, zirconium, niobium, molybdenum, technetium, ruthenium, rhodium, palladium, silver, hafnium, tantalum, tungsten, rhenium, osmium, iridium, platinum, gold, aluminum, gallium, indium, germanium, tin, lead, arsenic, antimony, bismuth, selenium, or tellurium. Other suitable metal alloys or the intermetallic compounds are within the contemplated scope of the present disclosure. In some embodiments, the anisotropic transport material layer 18 may be formed by activating a surface or a surface portion of the barrier material layer 17 using a suitable catalyst and then the activated surface or surface portion of the barrier material layer 17 is subjected to a suitable deposition process as is known in the art of semiconductor fabrication, for example, but not limited to, PVD, CVD, ALD, PEALD, or PECVD, at a temperature ranging from about 100° C. to about 1000° C., such that the anisotropic transport material layer 18 is formed in a layer-by-layer manner on the activated surface or surface portion of the barrier layer 17. Other suitable deposition techniques are within the contemplated scope of the present disclosure.

Referring to FIG. 1 and the example illustrated in FIG. 5, the method 100A proceeds to step 9A, where a planarization process (for example, but not limited to, a CMP process) is performed to remove excess of the anisotropic transport material layer 18 and the barrier material layer 17 over the dielectric layer 15 (see FIG. 4) so as to form a plurality of conductive interconnects 19, which are disposed in the dielectric layer 15 and are separated from each other. In some embodiments, the conductive interconnects 19 serve as metal lines. Only one of the conductive interconnects 19 is shown in FIG. 5. Each of the conductive interconnects 19 includes a conductive bulk region 18′ made from the anisotropic transport material layer 18 and a barrier layer 17′ made from the barrier material layer 17. The conductive interconnects 19 and the dielectric layer 15 are cooperatively configured as an interconnect layer 20 serving as a metal line layer (Mₓ₊₁).

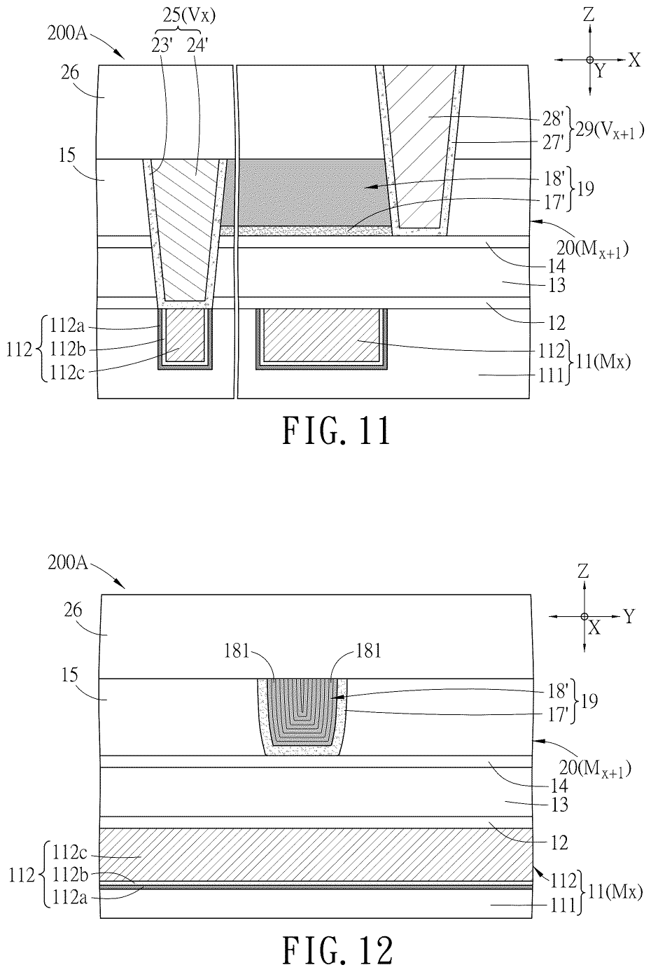

Referring the examples illustrated in FIGS. 10, 11, and 12, in which FIG. 11 is a schematic sectional view taken along line A-A of FIG. 10 and FIG. 12 is a schematic sectional view taken along line B-B of FIG. 10, the conductive bulk region 18′ is formed from the anisotropic transport material layer 18 (see FIG. 4) and includes a plurality of anisotropic transport material films 181, each of which includes the material for forming the anisotropic transport material layer 18. The anisotropic transport material films 181 are formed on the barrier layer 17′ in a layer-by-layer manner, and extend in a carrier-transport direction (for example, an electron-transport direction) in the conductive bulk region 18′ of the conductive interconnects 19. In some embodiments, the carrier-transport direction is parallel to a lengthwise direction of the conductive interconnects 19. In some embodiments, the lengthwise direction of the conductive interconnects 19 is the X direction. In some embodiments, each of the anisotropic transport material films 181 is formed as a U-shaped configuration (see FIG. 12).

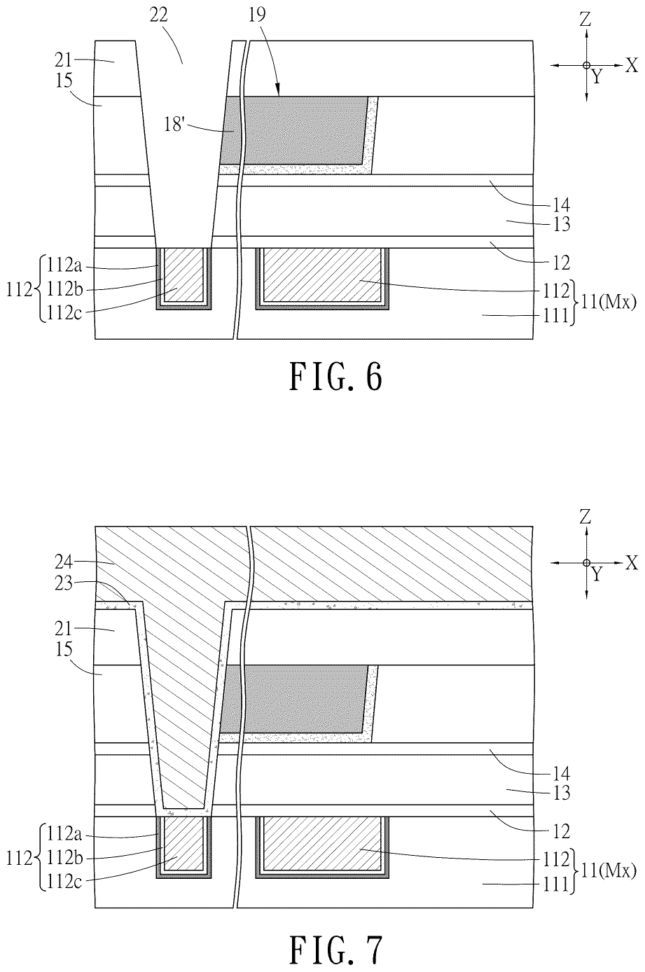

Referring to FIG. 1 and the examples illustrated in FIGS. 6-9 and 11, the method 100A proceeds to step 10A, where a conductive interconnect 25 and a conductive interconnect 29 are formed at two opposite sides of a corresponding one of the conductive interconnects 19 in the carrier-transport direction (i.e., the lengthwise direction) of the conductive interconnects 19. In some embodiments, the conductive interconnect 25 serves as a contact via (Vₓ), which is laterally connected to the corresponding one of the conductive interconnects 19 and which penetrates the dielectric layer 15, the etch stop layer 14, the dielectric layer 13, and the etch stop layer 12 so as to be connected to a corresponding one of the conductive interconnects 112, so that the corresponding one of the conductive interconnects 112 is electrically connected to the corresponding one of the conductive interconnects 19 through the connective interconnect 25. In some embodiments, the conductive interconnect 25 may be formed by sub-steps (i) to (iv) described hereinafter.

Referring to the example illustrated in FIG. 6, in sub-step (i), a dielectric layer 21 is formed on the structure shown in FIG. 5. The material and the process for forming the dielectric layer 21 may be the same as or similar to those for forming the dielectric layer 111 described above in step 1A, and details thereof are omitted for the sake of brevity. In sub-step (ii), a via hole 22 is formed to penetrate the dielectric layer 21, the dielectric layer 15, the etch stop layer 14, the dielectric layer 13, and the etch stop layer 12 so as to expose the corresponding one of the conductive interconnects 112 through the via hole 22. The via hole 22 may be formed by a process similar to the process for forming the trenches described above in step 1A, and details thereof are omitted for the sake of brevity. An end portion of the corresponding one of the conductive interconnects 19 is removed during the formation of the via hole 22.

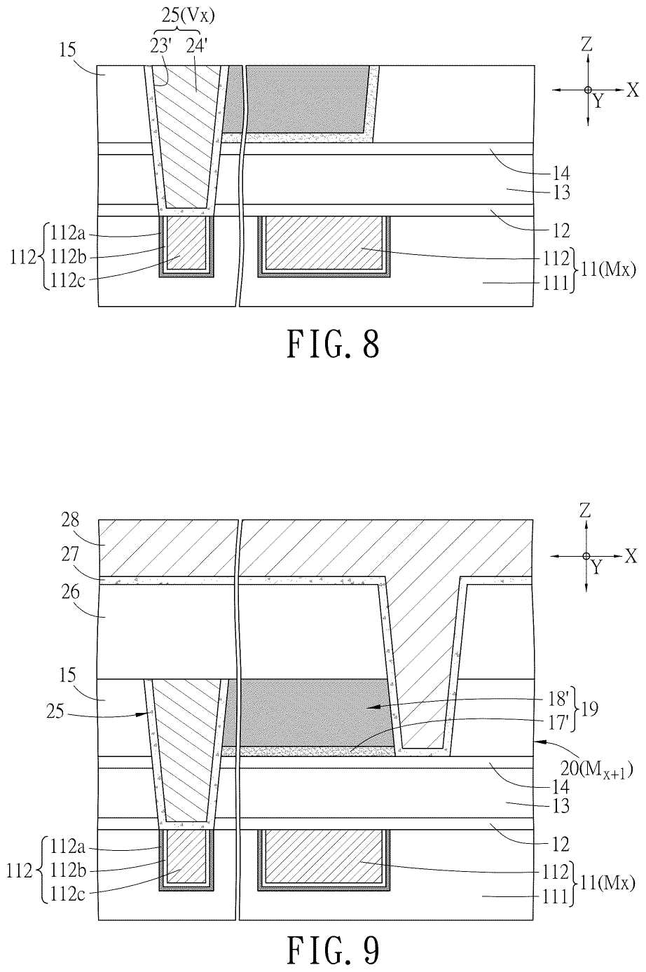

Referring to the example illustrated in FIG. 7, in sub-step (iii), a barrier material layer 23 is conformally deposited on the structure shown in FIG. 6 and a conductive metal layer 24 is formed on the barrier material layer 23 to fill the via hole 22 (see FIG. 6). In some embodiments, the conductive metal layer 24 may be subjected to an annealing process so as to improve crystallinity of the conductive metal layer 24 and to reduce resistivity of the conductive metal layer 24 (or a conductive bulk region 24′ (see FIG. 8) formed thereafter). In some embodiments, the annealing process is a rapid thermal annealing process, a laser annealing process, a furnace annealing process, or the like. In some embodiments, the annealing process may be performed at a temperature ranging from about 100° C. to about 1400° C. In sub-step (iv), excess of the conductive metal layer 24, excess of the barrier material layer 23, and the dielectric layer 21 disposed over the dielectric layer 15 are removed by a planarization process (for example, but not limited to, a CMP process) to form the conductive interconnect 25, which includes a barrier layer 23′ and a conductive bulk region 24′ surrounded by the barrier layer 23′. The barrier layer 23′ is formed from the barrier material layer 23, and the conductive bulk region 24′ is formed from the conductive metal layer 24. The materials for the processes for forming the barrier material layer 23 and the conductive metal layer 24 may be the same as or similar to those for forming the barrier material layer and the bulk metal layer described above in step 1A, and details thereof are omitted for the sake of brevity.

Referring to the example illustrated in FIG. 9, in some embodiments, the conductive interconnect 29 serves as a contact via (Vₓ₊₁), which is laterally connected to the corresponding one of the conductive interconnects 19 and which extends upwardly in the Z direction so as to be connected to a corresponding one of conductive interconnects (not shown) formed on the conductive interconnect 29. In some embodiments, the conductive interconnect 29 may be formed by sub-steps (i) to (iv) described hereinafter.

Referring to the example illustrated in FIG. 9, in sub-step (i), a dielectric layer 26 is formed on the structure shown in FIG. 8. The material and the process for forming the dielectric layer 26 may be the same as or similar to those for forming the dielectric layer 111 described above in step 1A, and details thereof are omitted for the sake of brevity. In sub-step (ii), a via hole (not shown) is formed to penetrate the dielectric layer 26 and the dielectric layer 15 such that the via hole terminates at the etch stop layer 14. The via hole may be formed by a process similar to the process for forming the trenches described above in step 1A, and details thereof are omitted for the sake of brevity. An end portion of the corresponding one of the conductive interconnects 19 opposite to the conductive interconnect 25 is removed during the formation of the via hole. In sub-step (iii), a barrier material layer 27 is conformally deposited on the structure obtained after formation of the via hole and a conductive metal layer 28 is formed on the barrier material layer 27 to fill the via hole. Similarly, the annealing process described above for the conductive metal layer 24 may be performed so as to improve crystallinity of the conductive metal layer 28 and to reduce resistivity of the conductive metal layer 28 (or a conductive bulk region 28′ (see FIG. 11) formed thereafter). In sub-step (iv), excess of the conductive metal layer 28 and excess of the barrier material layer 27 disposed over the dielectric layer 26 are removed by a planarization process (for example, but not limited to, a CMP process) to form the conductive interconnect 29, which includes a barrier layer 27′ and a conductive bulk region 28′ surrounded by the barrier layer 27′. The barrier layer 27′ is formed from the barrier material layer 27, and the conductive bulk region 28′ is formed from the conductive metal layer 28. The materials for the processes for forming the barrier material layer 27 and the conductive metal layer 28 may be the same as or similar to those for forming the barrier material layer and the conductive metal layer described above in step 1A, and details thereof are omitted for the sake of brevity. The semiconductor device 200A is obtained accordingly.

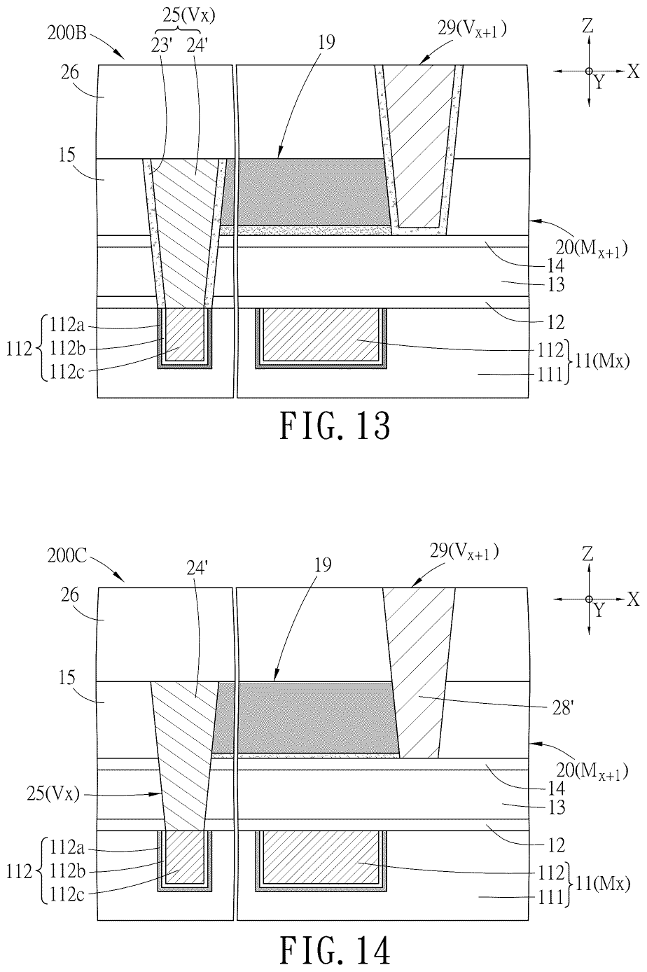

Referring to the example illustrated in FIG. 13, a semiconductor device 200B shown in FIG. 13 has a configuration similar to that of the semiconductor device 200A shown in FIG. 11, except that the conductive bulk region 24′ of the conductive interconnect 25 is in contact with the conductive bulk region 112c of a corresponding one of the conductive interconnects 112 and that the barrier layer 23′ of the conductive interconnect 25 only laterally covers the conductive bulk region 24′. In some embodiments, the conductive interconnect 25 of the semiconductor device 200B may be formed by the processes similar to those for forming the conductive interconnect 25 of the semiconductor device 200A described above with reference to FIGS. 6 to 8, except that a blocking layer (not shown) is formed on the corresponding one of the conductive interconnects 112 exposed through the via hole 22 (see FIG. 6) before the barrier material layer 23 is deposited and that the blocking layer is removed after the barrier material layer 23 is formed. In some embodiments, the blocking layer may be made of an inhibitor, such as a self-assembling monolayer (SAM) material, which includes a head group containing nitrogen, phosphorus, sulfur, or silicon. Examples of the SAM material including a nitrogen-containing head group include, for example, but not limited to, octylamine, octadecylamine, or the like. Examples of the SAM material including a phosphorus-containing head group include, for example, but not limited to, octylphosphonic acid, octadecylphosphonic acid, or the like. Examples of the SAM material including a sulfur-containing head group include, for example, but not limited to, 1-octanethiol, 1-octadecanethiol, or the like. Examples of the SAM material including a silicon-containing head group include, for example, but not limited to, triethoxy(octyl)silane, trimethoxy(octadecyl)silane, or the like.

Referring to the example illustrated in FIG. 14, a semiconductor device 200C shown in FIG. 14 has a configuration similar to that of the semiconductor device 200A shown in FIG. 11, except that the conductive interconnect 25 only includes the conductive bulk region 24′ without the barrier layer 23′ (see FIG. 11) and that the conductive interconnect 29 only includes the conductive bulk region 28′ without the barrier layer 27′ (see FIG. 11).

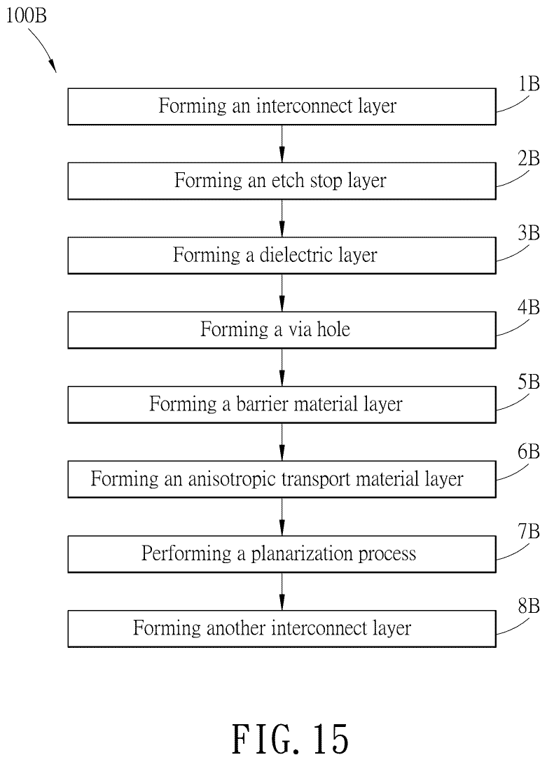

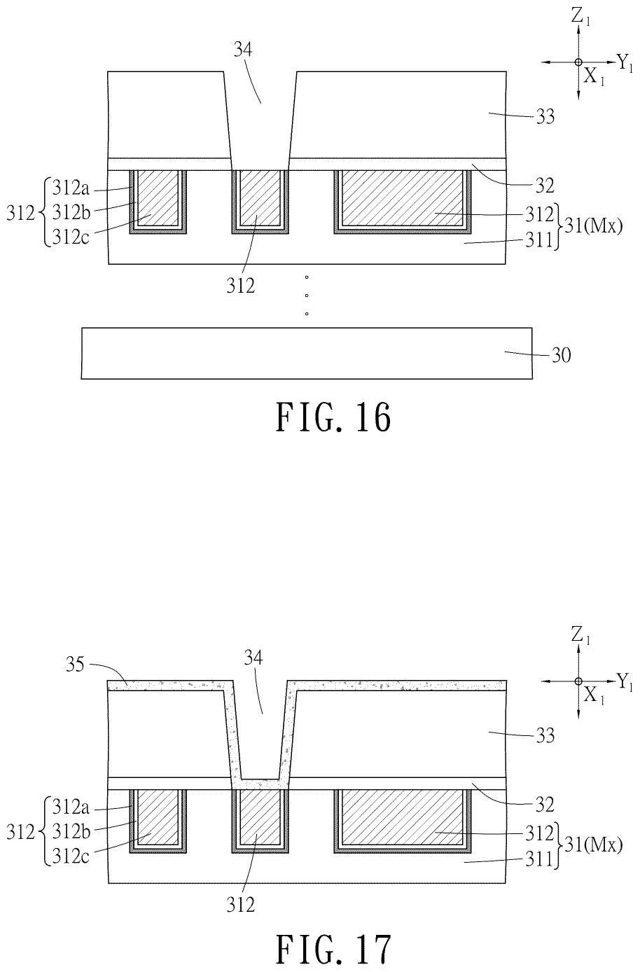

FIG. 15 is a flow diagram illustrating a method 100B for manufacturing a semiconductor device (for example, a semiconductor device 200D shown in FIGS. 20, 21, and 22) in accordance with some embodiments. FIGS. 16 to 19 illustrate schematic views of some intermediate stages of the method 100B. Some portions may be omitted in FIGS. 16 to 22 for the sake of brevity. Additional steps can be provided before, after or during the method 100B, and some of the steps described herein may be replaced by other steps or be eliminated.

Referring to FIG. 15 and the example illustrated in FIG. 16, the method 100B begins at step 1B, where an interconnect layer 31 is formed over a substrate 30 in a Z₁ direction normal to the substrate 30. The material for the substrate 30 is the same as or similar to that for the substrate 10 described above in step 1A of the method 100A, and details thereof are omitted for the sake of brevity.

In some embodiments, the interconnect layer 31 serves as a metal line layer (Mₓ), and includes a dielectric layer 311 (i.e., an inter-metal dielectric layer) and a plurality of conductive interconnects (for example, metal lines) 312 disposed in the dielectric layer 311 and separated from each other. In some embodiments, the conductive interconnects 312 extend in an X₁ direction transverse to the Z₁ direction and are spaced apart from each other in a Y₁ direction transverse to the X₁ direction and the Z₁ direction. In some embodiments, the X₁, Y₁ and Z₁ directions are perpendicular to one another. The material and the process for forming the dielectric layer 311 are the same as or similar to those for forming the dielectric layer 111 described above in step 1A of the method 100A, and details thereof are omitted for the sake of brevity. In some embodiments, each of the conductive interconnects 312 serving as the metal lines has a dimension ranging from about 1 nm to about 250 nm, and includes a barrier layer 312a, a liner layer 312b disposed on the barrier layer 312a, and a conductive bulk region 312c disposed on the liner layer 312b and separated from the barrier layer 312a by the liner layer 312b. The materials and the processes for forming the conductive interconnects 312 are the same as or similar to those for forming the conductive interconnects 112 described above in step 1A of the method 100A, and details thereof are omitted for the sake of brevity.

Referring to FIG. 15 and the example illustrated in FIG. 16, the method 100B proceeds to step 2B, where an etch stop layer 32 is formed on the interconnect layer 31. The material and the process for forming the etch stop layer 32 are the same as or similar to those for forming the etch stop layer 12 described above in step 2A of the method 100A, and details thereof are omitted for the sake of brevity.

Referring to FIG. 15 and the example illustrated in FIG. 16, the method 100B proceeds to step 3B, where a dielectric layer 33 is formed on the etch stop layer 32 opposite to the interconnect layer 31. The material and the process for forming the dielectric layer 33 may be the same as or similar to those for forming the dielectric layer 111 described above in step 1A, and details thereof are omitted for the sake of brevity.

Referring to FIG. 15 and the example illustrated in FIG. 16, the method 100B proceeds to step 4B, where a via hole 34 is formed to penetrate the dielectric layer 33 and the etch stop layer 32 so as to expose a corresponding one of the conductive interconnects 312 through the via hole 34. The process for forming the via hole 34 is similar to that for forming the trenches described above in step 1A, and details thereof are omitted for the sake of brevity.

Referring to FIG. 15 and the example illustrated in FIG. 17, the method 100B proceeds to step 5B, where a barrier material layer 35 is conformally formed on the structure shown in FIG. 16. The material and the process for forming the barrier material layer 35 are the same as or similar to those for forming the barrier material layer described above in step 1A, and details thereof are omitted for the sake of brevity.

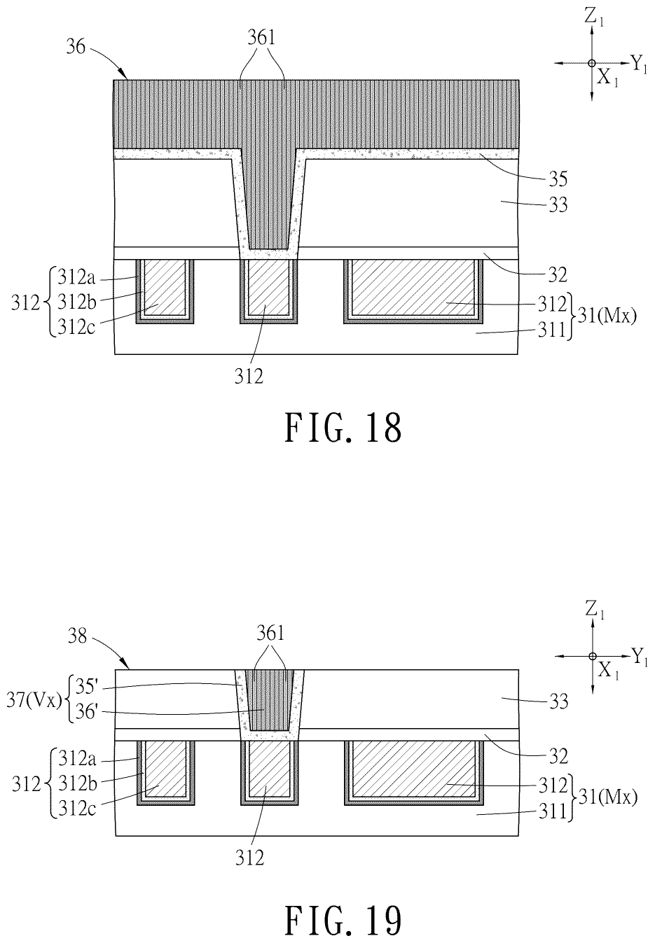

Referring to FIG. 15 and the example illustrated in FIG. 18, the method 100B proceeds to step 6B, where an anisotropic transport material layer 36 is formed on the barrier material layer 35 to fill the via hole 34 (see FIG. 17). The material and the processes for forming the anisotropic transport material layer 36 are the same as or similar to those for forming the anisotropic transport material layer 18 described above in step 8A of the method 100A, and details thereof are omitted for the sake of brevity. The anisotropic transport material layer 36 includes a plurality of anisotropic transport material films 361. In some embodiments, the anisotropic transport material films 361 are formed in a layer-by-layer manner so as to be stacked on one another in the Y₁ direction, and each of the anisotropic transport material films 361 is formed as a flat film extending in the X₁ direction and the Z₁ direction.

Referring to FIG. 15 and the example illustrated in FIG. 19, the method 100B proceeds to step 7B, where a planarization process (for example, but not limited to, a CMP process) is performed to remove excess of the anisotropic transport material layer 36 and excess of the barrier material layer 35 over the dielectric layer 33 (see FIG. 18) so as to form an conductive interconnect 37, which is disposed in the dielectric layer 33 and which is connected to a corresponding one of the conducive interconnects 312. In some embodiments, the conductive interconnect 37 serves as a contact via (Vx). The conductive interconnect 37 includes a barrier layer 35′ and a conductive bulk region 36′ surrounded by the barrier layer 35′. The barrier layer 35′ is formed from the barrier material layer 35, and the conductive bulk region 36′ is formed from the anisotropic transport material layer 36. The conductive interconnect 37 and the dielectric layer 33 are cooperatively configured as an interconnect layer 38 serving as a contact via layer.

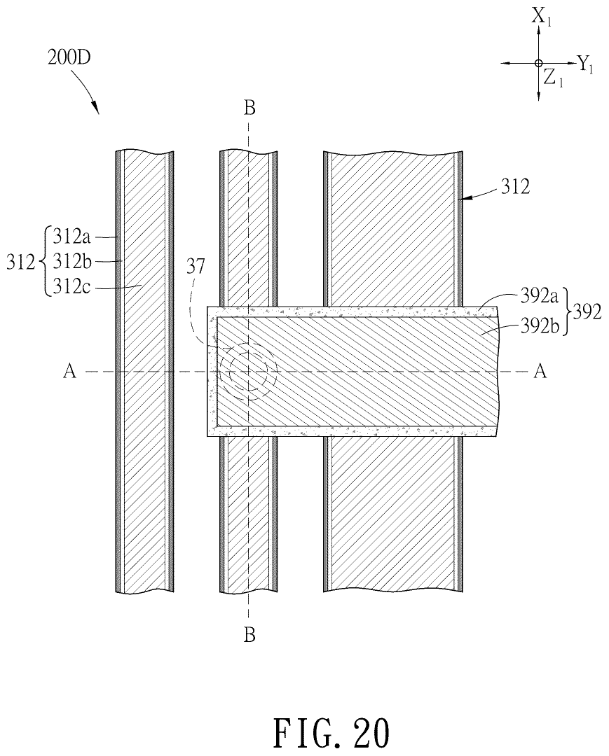

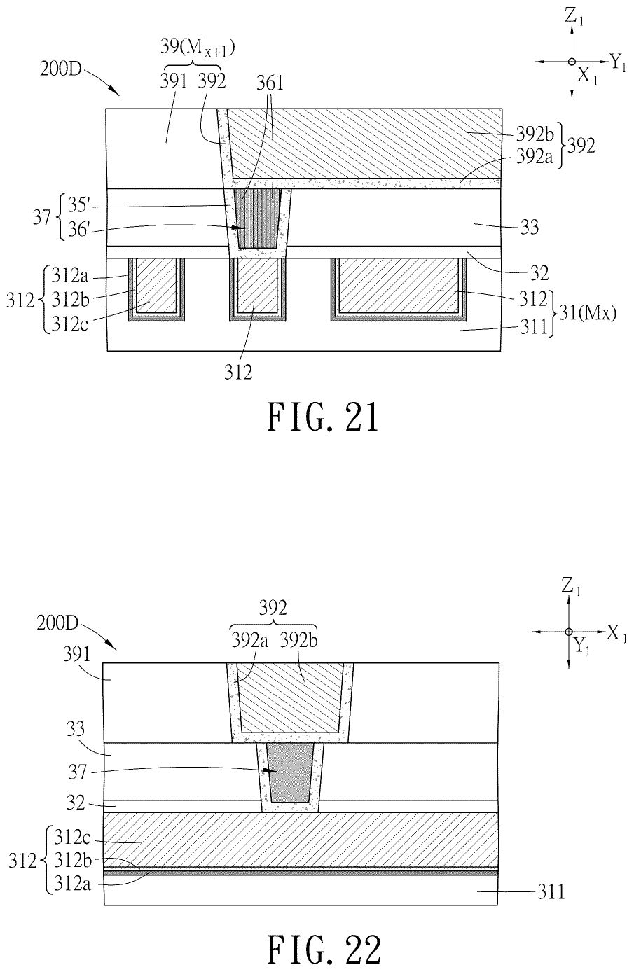

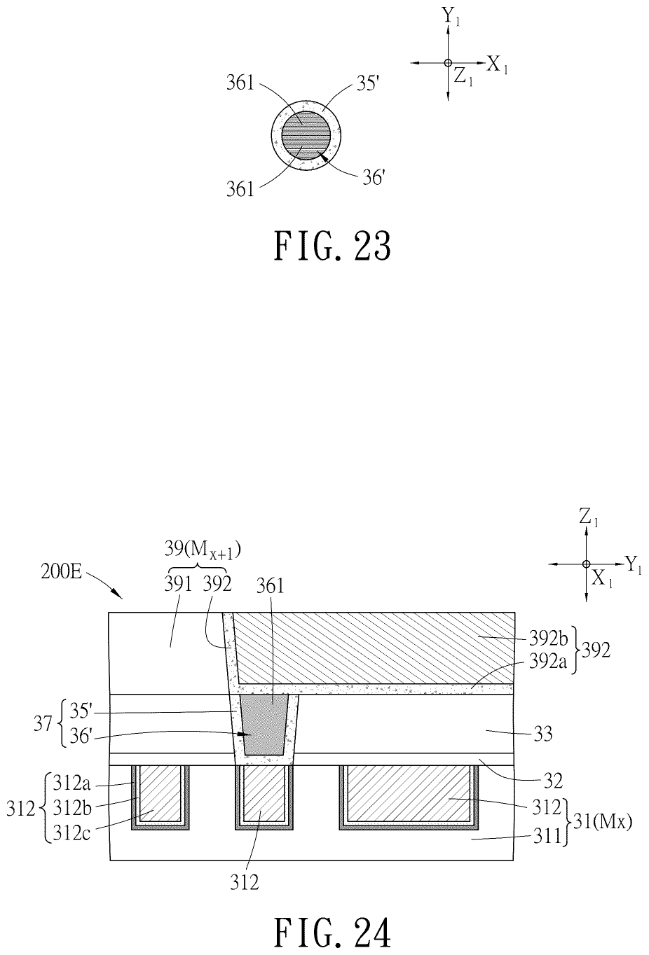

Referring the examples illustrated in FIGS. 20, 21, and 22, in which FIG. 21 is a schematic sectional view taken along line A-A of FIG. 20 and FIG. 22 is a schematic sectional view taken along line B-B of FIG. 20, the conductive bulk region 36′ of the conductive interconnect 37 is formed from the anisotropic transport material layer 36 (see FIG. 18) and includes a plurality of anisotropic transport material films 361. The anisotropic transport material films 361 are formed on the barrier layer 35′ in a layer-by-layer manner, and extend in a carrier-transport direction (for example, an electron-transport direction) in conductive bulk region 36′ of the conductive interconnect 37. In some embodiments, the carrier-transport direction in the conductive bulk region 36′ of the conductive interconnect 37 is parallel to a heightwise direction of the conductive interconnect 37. In some embodiments, the heightwise direction of the conductive interconnect 37 is the Z₁ direction. In some embodiments, each of the anisotropic transport material films 361 is formed as a flat film configuration. Referring to the examples illustrated in FIGS. 21 and 23, each of the anisotropic transport material films 361 extends in the X₁ direction.

Referring to FIG. 15 and the examples illustrated in FIGS. 20 to 22, the method 100B proceeds to step 8B, where an interconnect layer 39 is formed on the interconnect layer 37. In some embodiments, the interconnect layer 39 serves as a metal line layer (Mₓ₊₁), and includes a dielectric layer 391 (i.e., an inter-metal dielectric layer) and a plurality of conductive interconnects (for example, metal lines) 392 disposed in the dielectric layer 391 and separated from each other. In some embodiments, the conductive interconnects 392 extend in the Y₁ direction and are spaced apart from each other in the X₁ direction. The material and the process for forming the dielectric layer 391 are the same as or similar to those for forming the dielectric layer 111 described above in step 1A of the method 100A, and details thereof are omitted for the sake of brevity. In some embodiments, each of the conductive interconnects 392 serving as the metal lines has a dimension ranging from about 1 nm to about 250 nm, and includes a barrier layer 392a and a conductive bulk region 392b disposed on the barrier layer 392a. The materials and the processes for forming the conductive interconnects 392 are the same as or similar to those for forming the conductive interconnects 112 described above in step 1A of the method 100A, and details thereof are omitted for the sake of brevity. The semiconductor device 200D is obtained accordingly.

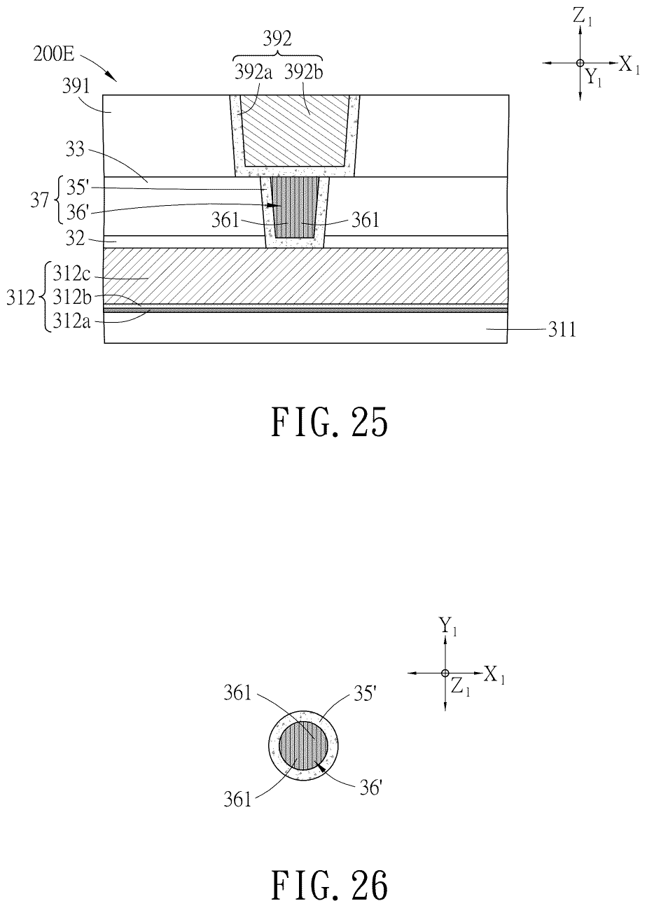

Referring to the examples illustrated in FIGS. 24 to 26, a semiconductor device 200E shown in FIGS. 24 and 25 has a configuration similar to that of the semiconductor device 200D shown in FIGS. 21 and 22, except that in the semiconductor device 200E, each of the anisotropic transport material films 361 is formed as a flat film extending in the Y₁ direction and the Z₁ direction.

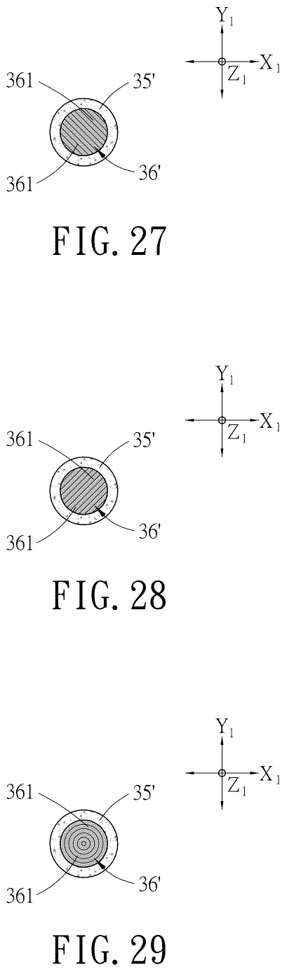

Referring to the examples illustrated in FIGS. 27 to 29, each of the anisotropic transport material films 361 is formed as a flat film extending in the Z₁ direction and a direction that is not perpendicular to the X₁ direction or Y₁ direction (see FIG. 27 or FIG. 28), or is formed as a cylindrical film (see FIG. 29).

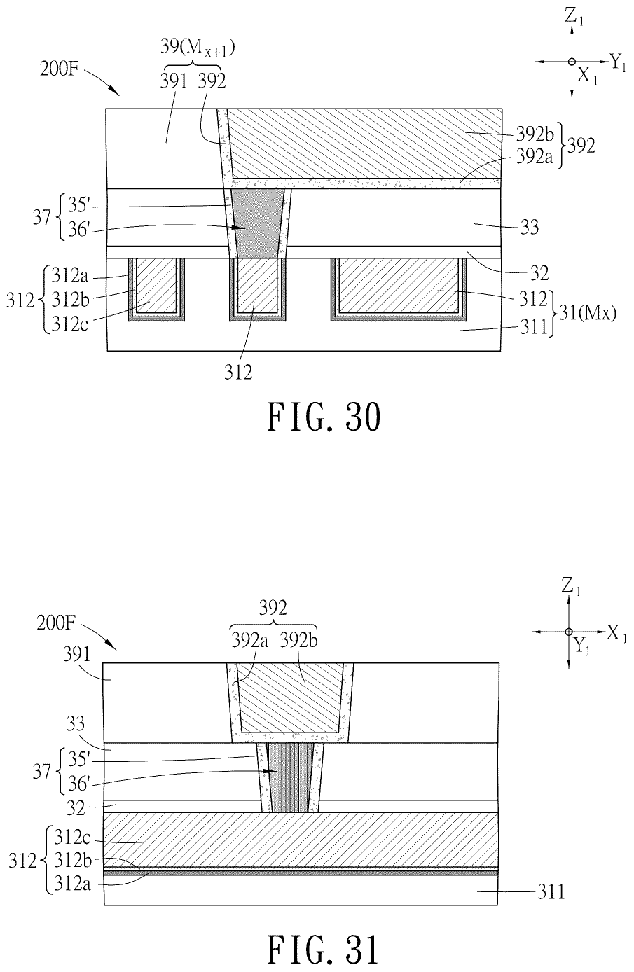

Referring to the examples illustrated in FIGS. 30 and 31, a semiconductor device 200F shown in FIGS. 30 and 31 has a configuration similar to that of the semiconductor device 200E shown in FIGS. 24 and 25, except that in the semiconductor device 200F, the conductive bulk region 36′ of the conductive interconnect 37 is in contact with the conductive bulk region 312c of a corresponding one of the conductive interconnects 312 and the barrier layer 35′ of the conductive interconnect 37 only laterally covers the conductive bulk region 36′. The barrier layer 35′ of the conductive interconnect 37 of the semiconductor device 200F may be formed by the processes similar to those for forming the barrier layer 23′ of the conductive interconnect 25 of the semiconductor device 200B.

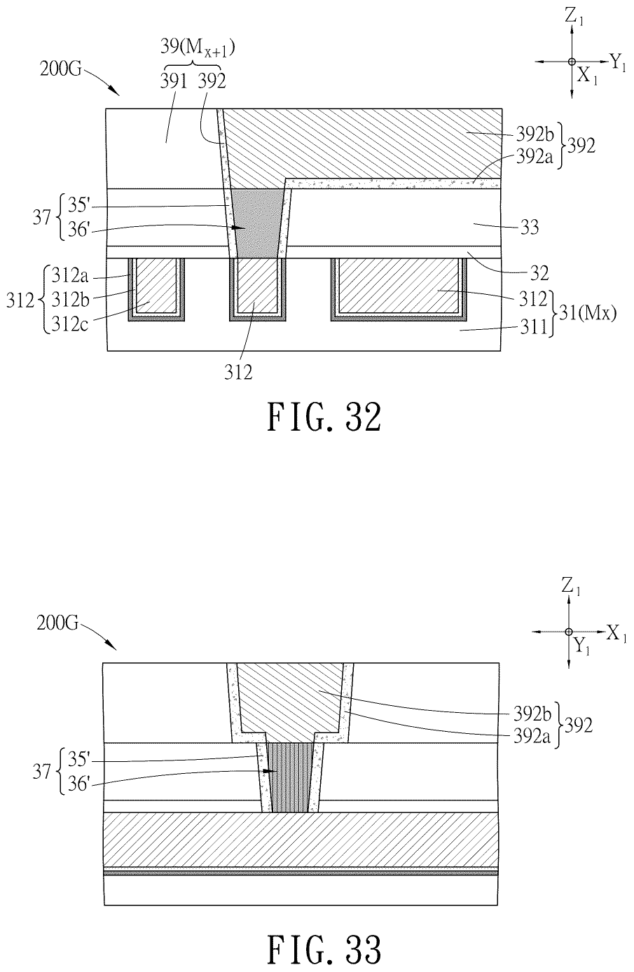

Referring to the examples illustrated in FIGS. 32 and 33, a semiconductor device 200G shown in FIGS. 32 and 33 has a configuration similar to that of the semiconductor device 200F shown in FIGS. 30 and 31, except that in the semiconductor device 200G, the conductive bulk region 36′ of the conductive interconnect 37 is in contact with the conductive bulk region 392b of a corresponding one of the conductive interconnects 392. The barrier layer 392a of the corresponding one of the conductive interconnects 392 of the semiconductor device 200G may be formed by the processes similar to those for forming the barrier layer 23′ of the conductive interconnect 25 of the semiconductor device 200B.

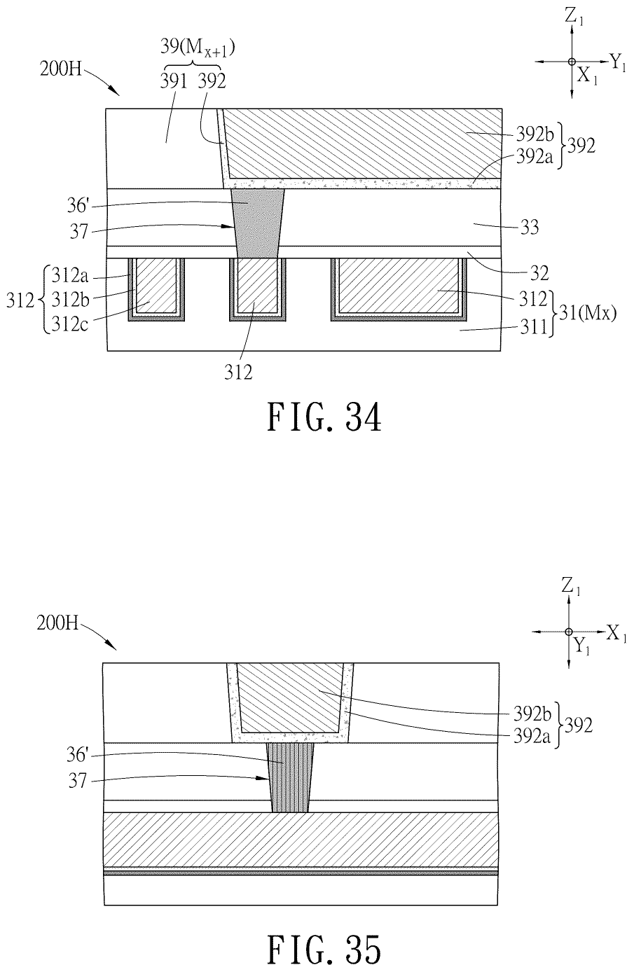

Referring to the examples illustrated in FIGS. 34 and 35, a semiconductor device 200H shown in FIGS. 34 and 35 has a configuration similar to that of the semiconductor device 200F shown in FIGS. 30 and 31, except that in the semiconductor device 200H, the conductive interconnect 37 only includes the conductive bulk region 36′ without the barrier layer 35′ (see FIGS. 30 and 31).

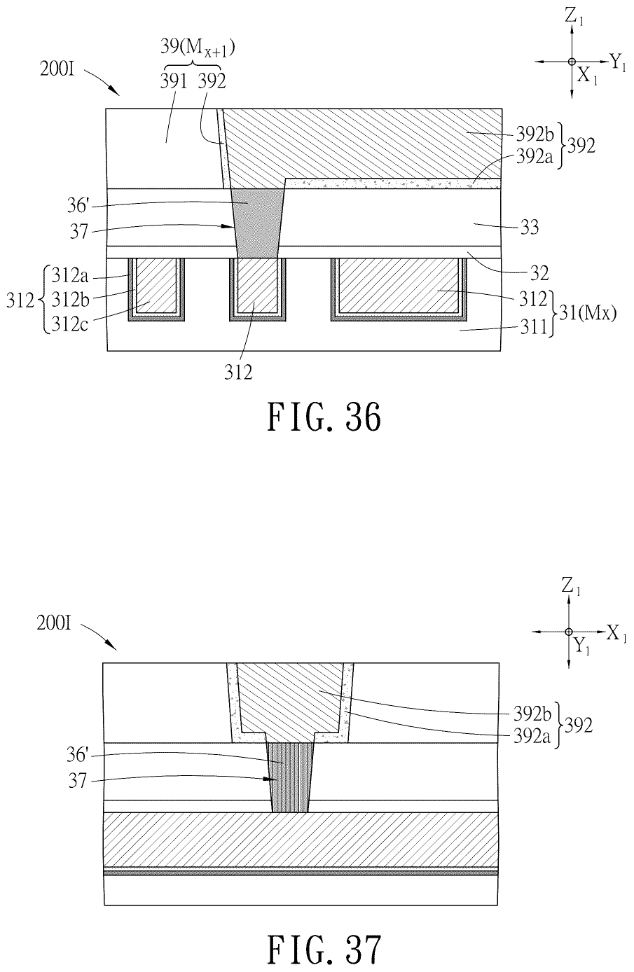

Referring to the examples illustrated in FIGS. 36 and 37, a semiconductor device 200I shown in FIGS. 36 and 37 has a configuration similar to that of the semiconductor device 200G shown in FIGS. 32 and 33, except that in the semiconductor device 200I, the conductive interconnect 37 only includes the conductive bulk region 36′ without the barrier layer 35′ (see FIGS. 32 and 33).

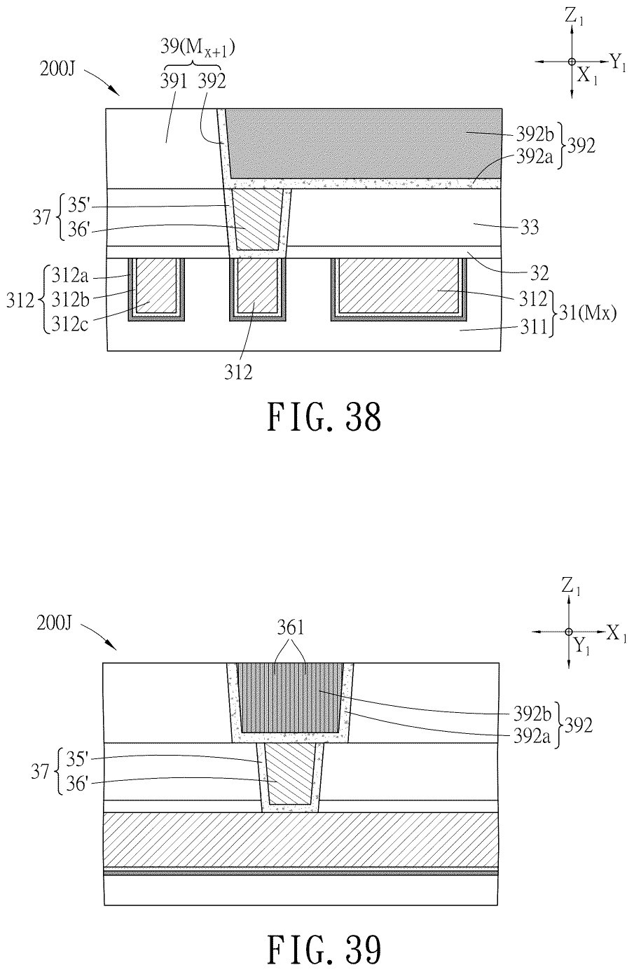

Referring to the examples illustrated in FIGS. 38 and 39, a semiconductor device 200J shown in FIGS. 38 and 39 has a configuration similar to that of the semiconductor device 200D shown in FIGS. 21 and 22, except that in the semiconductor device 200J, the conductive bulk region 392b of the conductive interconnects 392 is formed from the anisotropic transport material layer 36 for forming the conductive bulk region 36′ of the conductive interconnect 37 of the semiconductor device 200D and includes a plurality of the anisotropic transport material films 361, each of which is formed as a flat film extending in a lengthwise direction (for example, the Y₁ direction) of the conductive interconnects 392, and which are disposed in a layer-by-layer manner to be stacked on one another in a direction (for example, the X₁ direction) perpendicular to the lengthwise direction of the conductive interconnects 392; and the conductive bulk region 36′ of the conductive interconnect 37 is made from a conductive metal layer for forming the conductive bulk region 392b of the conductive interconnects 392 of the semiconductor device 200D.

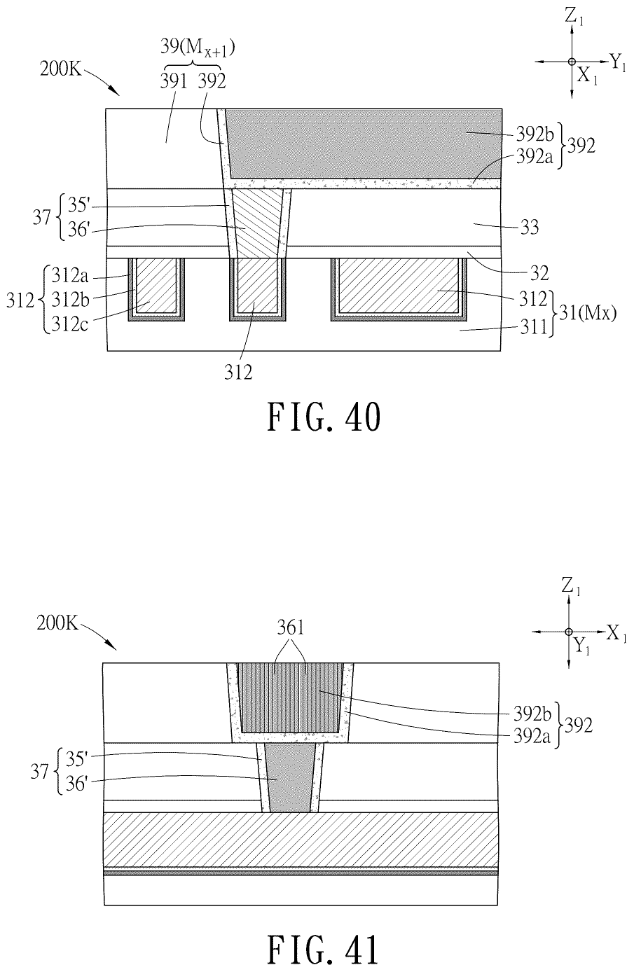

Referring to the examples illustrated in FIGS. 40 and 41, a semiconductor device 200K shown in FIGS. 40 and 41 has a configuration similar to that of the semiconductor device 200J shown in FIGS. 38 and 39, except that in the semiconductor device 200K, the conductive bulk region 36′ of the conductive interconnect 37 is in contact with the conductive bulk region 312c of a corresponding one of the conductive interconnects 312 and the barrier layer 35′ of the conductive interconnect 37 only laterally covers the conductive bulk region 36′.

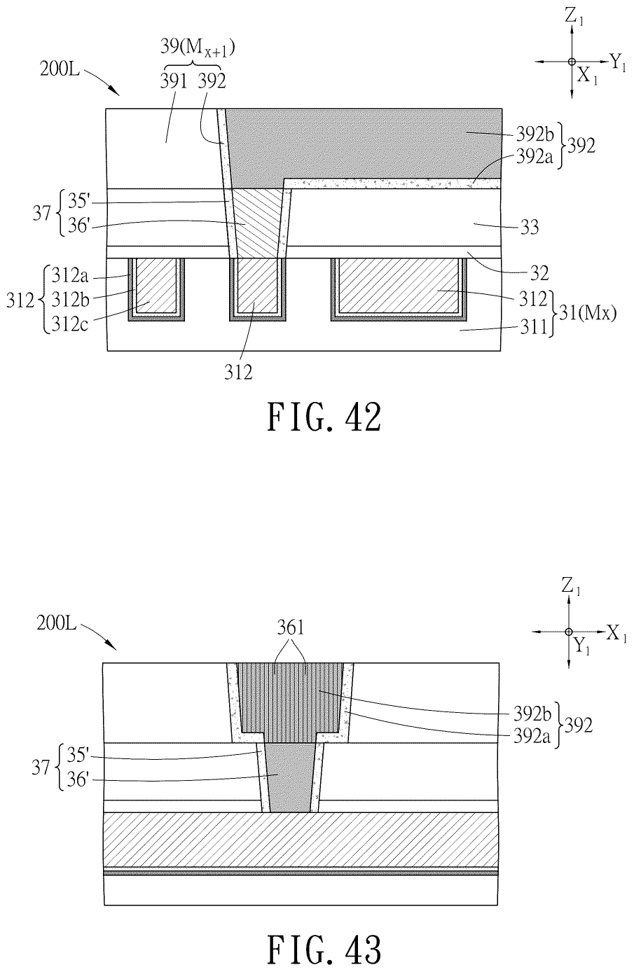

Referring to the examples illustrated in FIGS. 42 and 43, a semiconductor device 200L shown in FIGS. 42 and 43 has a configuration similar to that of the semiconductor device 200K shown in FIGS. 40 and 41, except that in the semiconductor device 200L, the conductive bulk region 36′ of the conductive interconnect 37 is in contact with the conductive bulk region 392b of a corresponding one of the conductive interconnects 392.

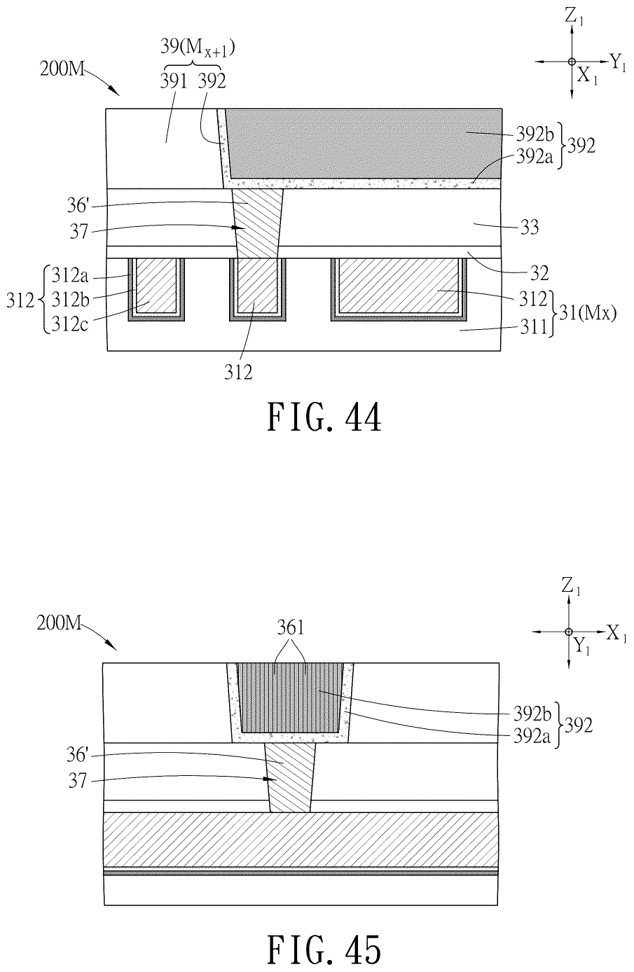

Referring to the examples illustrated in FIGS. 44 and 45, a semiconductor device 200M shown in FIGS. 44 and 45 has a configuration similar to that of the semiconductor device 200K shown in FIGS. 40 and 41, except that in the semiconductor device 200M, the conductive interconnect 37 only includes the conductive bulk region 36′ without the barrier layer 35′ (see FIGS. 40 and 41).

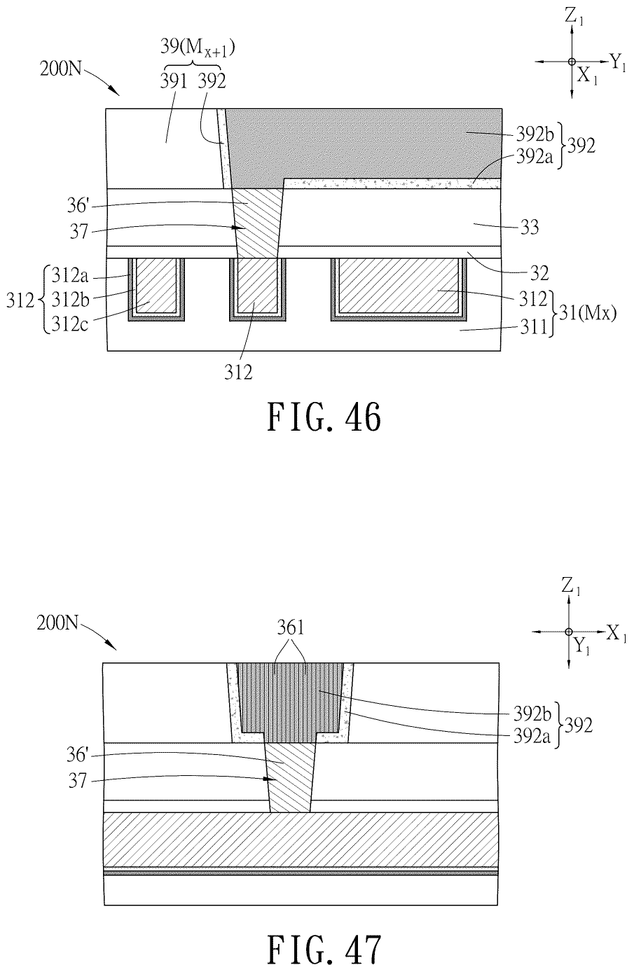

Referring to the examples illustrated in FIGS. 46 and 47, a semiconductor device 200N shown in FIGS. 46 and 47 has a configuration similar to that of the semiconductor device 200L shown in FIGS. 42 and 43, except that in the semiconductor device 200N, the conductive interconnect 37 only includes the conductive bulk region 36′ without the barrier layer 35′ (see FIGS. 42 and 43).

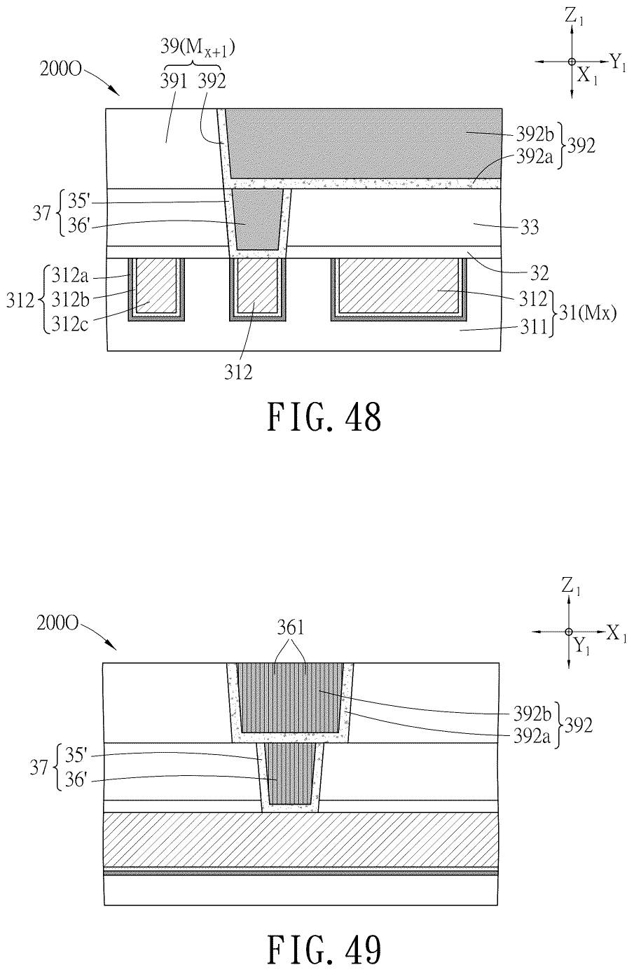

Referring to the examples illustrated in FIGS. 48 and 49, a semiconductor device 200O shown in FIGS. 48 and 49 has a configuration similar to that of the semiconductor device 200J shown in FIGS. 38 and 39, except that in the semiconductor device 2000, the conductive interconnect 37 has a configuration the same as that of the conductive interconnect 37 of the semiconductor device 200E (see FIGS. 24 and 25).

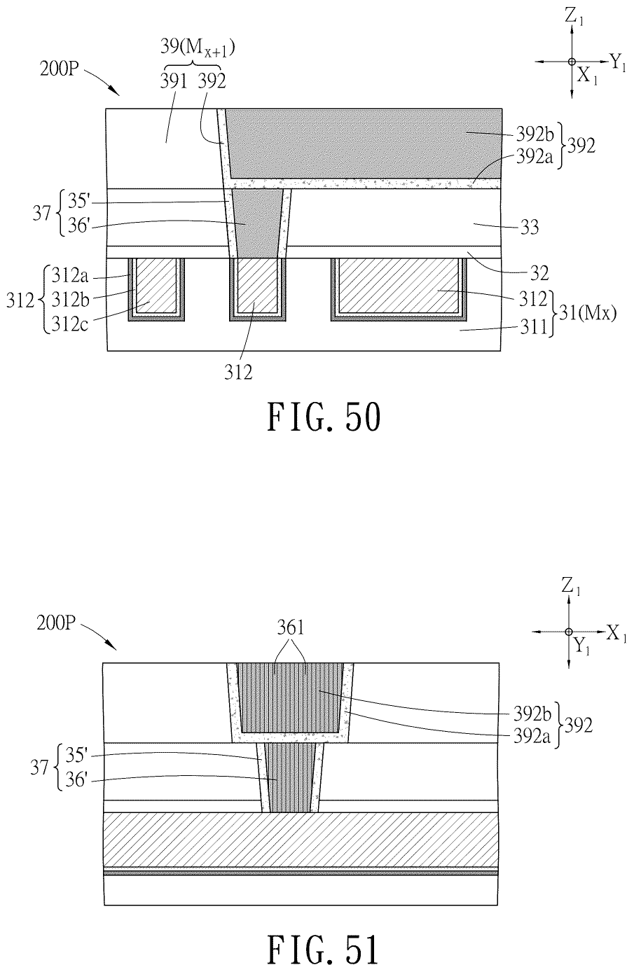

Referring to the examples illustrated in FIGS. 50 and 51, a semiconductor device 200P shown in FIGS. 50 and 51 has a configuration similar to that of the semiconductor device 200O shown in FIGS. 48 and 49, except that in the semiconductor device 200P, the conductive bulk region 36′ of the conductive interconnect 37 is in contact with the conductive bulk region 312c of a corresponding one of the conductive interconnects 312 and the barrier layer 35′ of the conductive interconnect 37 only laterally covers the conductive bulk region 36′.

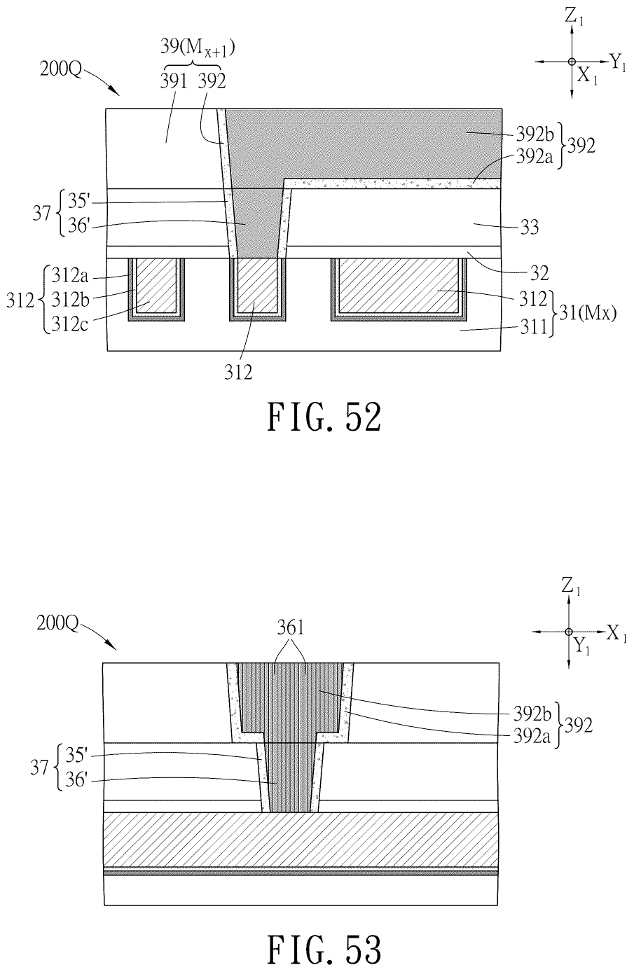

Referring to the examples illustrated in FIGS. 52 and 53, a semiconductor device 200Q shown in FIGS. 52 and 53 has a configuration similar to that of the semiconductor device 200P shown in FIGS. 50 and 51, except that in the semiconductor device 200Q, the conductive bulk region 36′ of the conductive interconnect 37 is in contact with the conductive bulk region 392b of a corresponding one of the conductive interconnects 392.

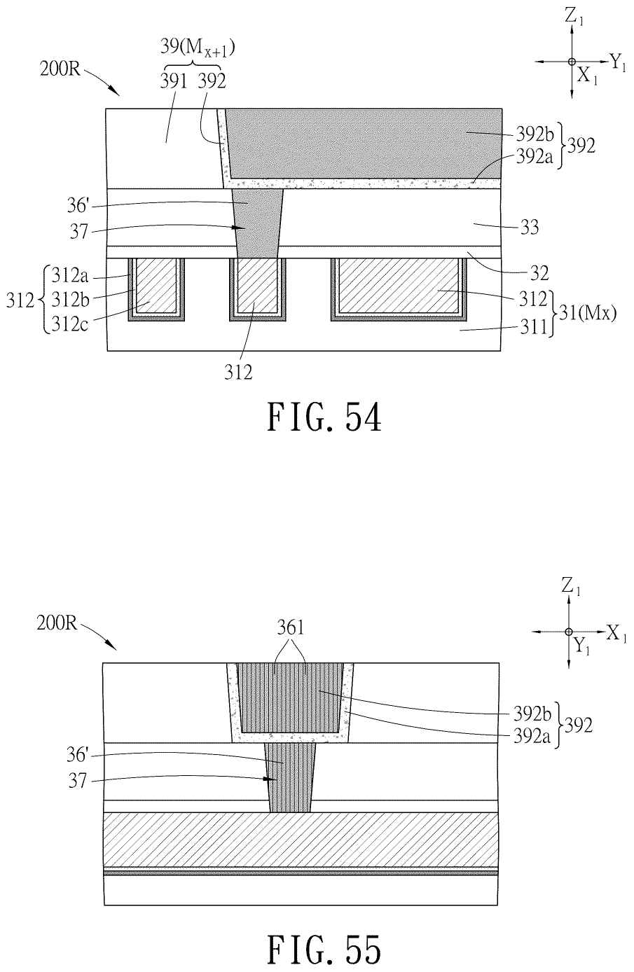

Referring to the examples illustrated in FIGS. 54 and 55, a semiconductor device 200R shown in FIGS. 54 and 55 has a configuration similar to that of the semiconductor device 200P shown in FIGS. 50 and 51, except that in the semiconductor device 200R, the conductive interconnect 37 only includes the conductive bulk region 36′ without the barrier layer 35′ (see FIGS. 50 and 51).

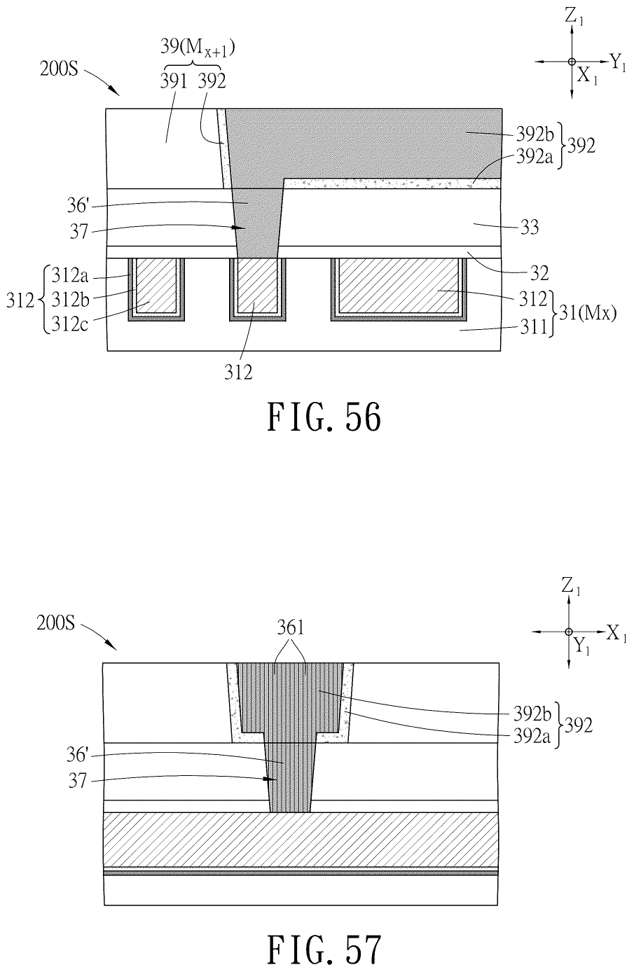

Referring to the examples illustrated in FIGS. 56 and 57, a semiconductor device 200S shown in FIGS. 56 and 57 has a configuration similar to that of the semiconductor device 200Q shown in FIGS. 52 and 53, except that in the semiconductor device 200S, the conductive interconnect 37 only includes the conductive bulk region 36′ without the barrier layer 35′ (see FIGS. 52 and 53).

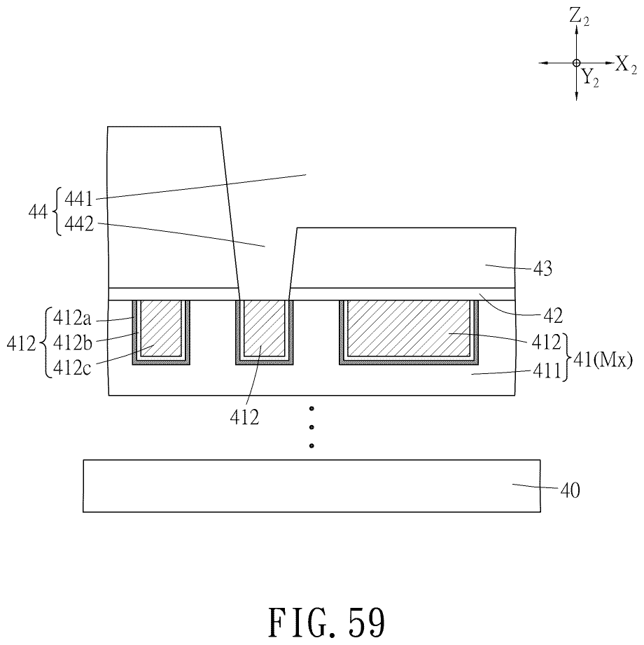

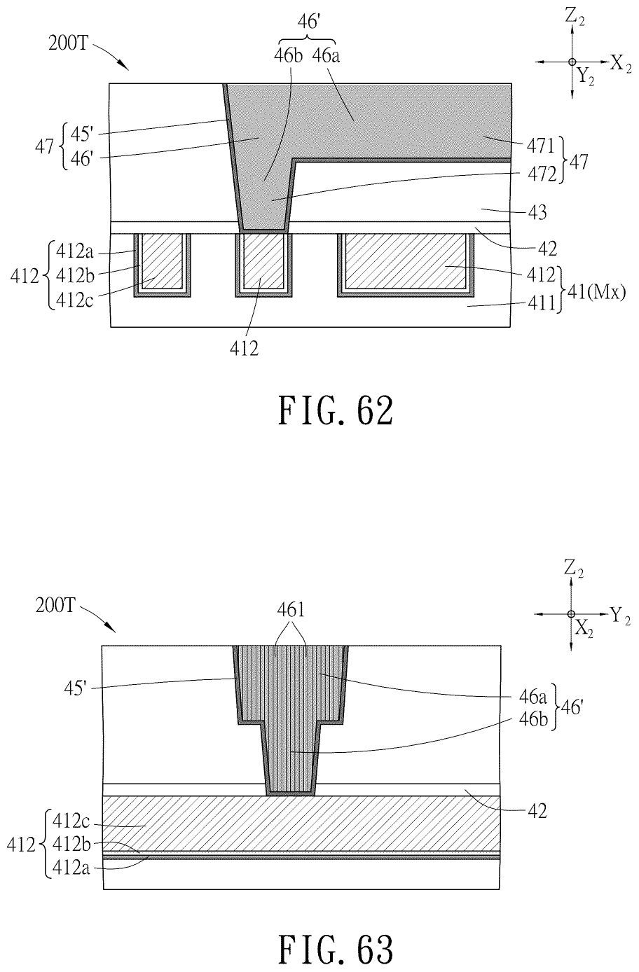

FIG. 18 is a flow diagram illustrating a method 100C for manufacturing a semiconductor device (for example, a semiconductor device 200T shown in FIGS. 62 and 63) in accordance with some embodiments. FIGS. 59 to 61 illustrate schematic views of some intermediate stages of the method 100C. Some portions may be omitted in FIGS. 59 to 63 for the sake of brevity. Additional steps can be provided before, after or during the method 100C, and some of the steps described herein may be replaced by other steps or be eliminated.

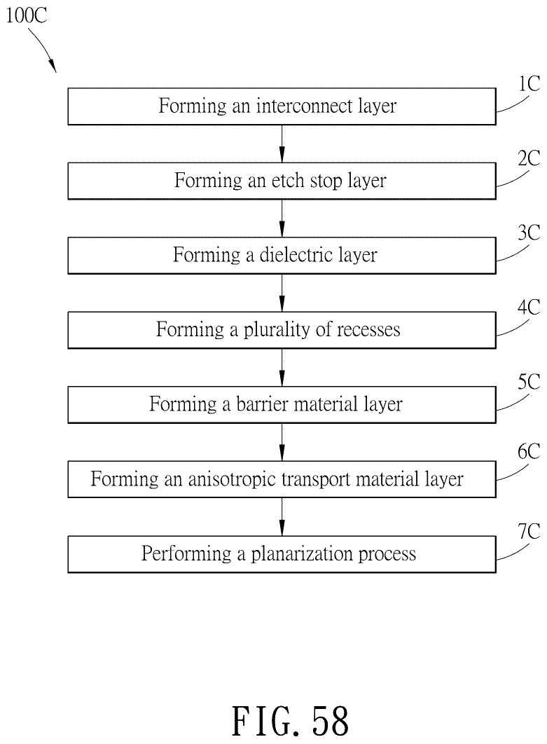

Referring to FIG. 58 and the example illustrated in FIG. 59, the method 100C begins at step 1C, where an interconnect layer 41 is formed over a substrate 40 in a Z₂ direction normal to the substrate 40. The material for the substrate 40 is the same as or similar to that for the substrate 10 described above in step 1A of the method 100A, and details thereof are omitted for the sake of brevity.

In some embodiments, the interconnect layer 41 serves as a metal line layer (Mₓ), and includes a dielectric layer 411 (i.e., an inter-metal dielectric layer) and a plurality of conductive interconnects (for example, metal lines) 412 disposed in the dielectric layer 411 and separated from each other. In some embodiments, the conductive interconnects 412 extend in an Y₂ direction transverse to the Z₂ direction, and are spaced apart from each other in a X₂ direction transverse to the Y₂ direction and the Z₂ direction. In some embodiments, the X₂, Y₂, and Z₂ directions are perpendicular to one another. The material and the process for forming the dielectric layer 411 are the same as or similar to those for forming the dielectric layer 111 described above in step 1A of the method 100A, and details thereof are omitted for the sake of brevity. In some embodiments, each of the conductive interconnects 412 serving as the metal lines has a dimension ranging from about 1 nm to about 250 nm, and includes a barrier layer 412a, a liner layer 412b disposed on the barrier layer 412a, and a conductive bulk region 412c disposed on the liner layer 412b and separated from the barrier layer 412a by the liner layer 412b. The materials and the processes for forming the conductive interconnects 412 are the same as or similar to those for forming the conductive interconnects 112 described above in step 1A of the method 100A, and details thereof are omitted for the sake of brevity.

Referring to FIG. 58 and the example illustrated in FIG. 59, the method 100C proceeds to step 2C, where an etch stop layer 42 is formed on the interconnect layer 41. The material and the process for forming the etch stop layer 42 are the same as or similar to those for forming the etch stop layer 12 described above in step 2A of the method 100A, and details thereof are omitted for the sake of brevity.

Referring to FIG. 58 and the example illustrated in FIG. 59, the method 100C proceeds to step 3C, where a dielectric layer 43 is formed on the etch stop layer 42 opposite to the interconnect layer 41. The material and the process for forming the dielectric layer 43 may be the same as or similar to those for forming the dielectric layer 111 described above in step 1A, and details thereof are omitted for the sake of brevity.

Referring to FIG. 58 and the example illustrated in FIG. 59, the method 100C proceeds to step 4C, where a plurality of recesses 44 are formed. At least one of the recesses 44 penetrates the dielectric layer 43 and the etch stop layer 42 so as to expose a corresponding one of the conductive interconnects 412 through the at least one of the recesses 44. The at least one of the recesses 44 includes a trench 441 recessed downwardly from a top surface of the dielectric layer 43 and extending in the X₂ direction, and a via hole 442 extending through the etch stop layer 42 and disposed below and in spatial communication with the trench 441. The process for forming the recesses 44 is similar to that for forming the trenches described above in step 1A, and details thereof are omitted for the sake of brevity.

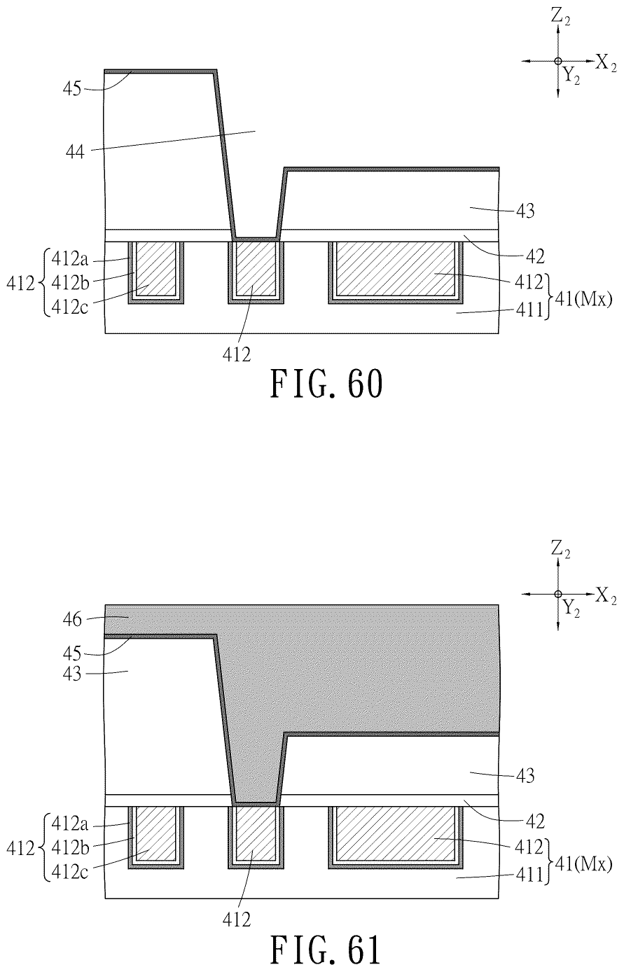

Referring to FIG. 58 and the example illustrated in FIG. 60, the method 100C proceeds to step 5C, where a barrier material layer 45 is conformally formed on the structure shown in FIG. 59. The material and the process for forming the barrier material layer 45 are the same as or similar to those for forming the barrier material layer described above in step 1A, and details thereof are omitted for the sake of brevity.

Referring to FIG. 58 and the example illustrated in FIG. 61, the method 100C proceeds to step 6C, where an anisotropic transport material layer 46 is formed on the barrier material layer 45 to fill the recesses 44 (see FIG. 60). The material and the processes for forming the anisotropic transport material layer 46 are the same as or similar to those for forming the anisotropic transport material layer 18 described above in step 8A of the method 100A, and details thereof are omitted for the sake of brevity. The anisotropic transport material layer 46 includes a plurality of anisotropic transport material films 461 (see FIG. 63). In some embodiments, the anisotropic transport material films 461 are formed in a layer-by-layer manner so as to be stacked on one another in the Y₂ direction, and each of the anisotropic transport material films 461 is formed as a flat film extending in the X₂ direction and the Z₂ direction.

Referring to FIG. 58 and the examples illustrated in FIGS. 62 and 63, the method 100C proceeds to step 7C, where a planarization process (for example, but not limited to, a CMP process) is performed to remove excess of the anisotropic transport material layer 46 and excess of the barrier material layer 45 over the dielectric layer 43 (see FIG. 61) so as to form a plurality of conductive interconnects 47 disposed in the dielectric layer 43 and spaced apart from each other. The semiconductor device 200T is obtained accordingly. Each of the conductive interconnects 47 includes a conductive bulk region 46′ and a barrier layer 45′ disposed between the dielectric layer 43 and the conductive bulk region 46′. The conductive bulk region 46′ is formed from the anisotropic transport material layer 46, and the barrier layer 45′ is formed from the barrier material layer 45. At least one of the conductive interconnects 47 includes an upper interconnect portion 471 extending in the X₂ direction (a lengthwise direction of the upper interconnect portion 471), and a lower interconnect portion 472 disposed below and integrated with the upper interconnect portion 471 and extending through the etch stop layer 42 so as to be connected to a corresponding one of the conductive interconnects 412. Each of remaining ones of the conducive interconnects 37 may only include the upper interconnect portion 471 without the lower interconnect portion 472. The upper interconnect portion 471 may serve as a metal line, and the lower interconnect portion 472 may serve as a contact via and is disposed between and connected to a corresponding one of the conductive interconnects 412 and the upper connect portion 471 of a corresponding one of the conductive interconnects 47. The conductive bulk region 46′ includes an upper conductive bulk portion 46a and a lower conductive bulk portion 46b disposed below and integrated with the upper conductive bulk portion 46a. The conductive bulk region 46′ is configured by a plurality of the anisotropic transport material films 461 disposed in a layer-by-layer manner so as to be stacked on one another in the Y₂ direction. Each of the anisotropic transport material films 461 is formed as a flat film extending in the X₂ direction and the Z₂ direction. Therefore, the anisotropic transport material films 461 included in the upper interconnect portion 471, which serves as a metal line, extend in a lengthwise direction (the X₂ direction) of the upper interconnect portion 471; and the anisotropic transport material films 461 included in the lower interconnect portion 472, which serves as a contact via, extend in a heightwise direction (the Z₂ direction) of the lower interconnect portion 472.

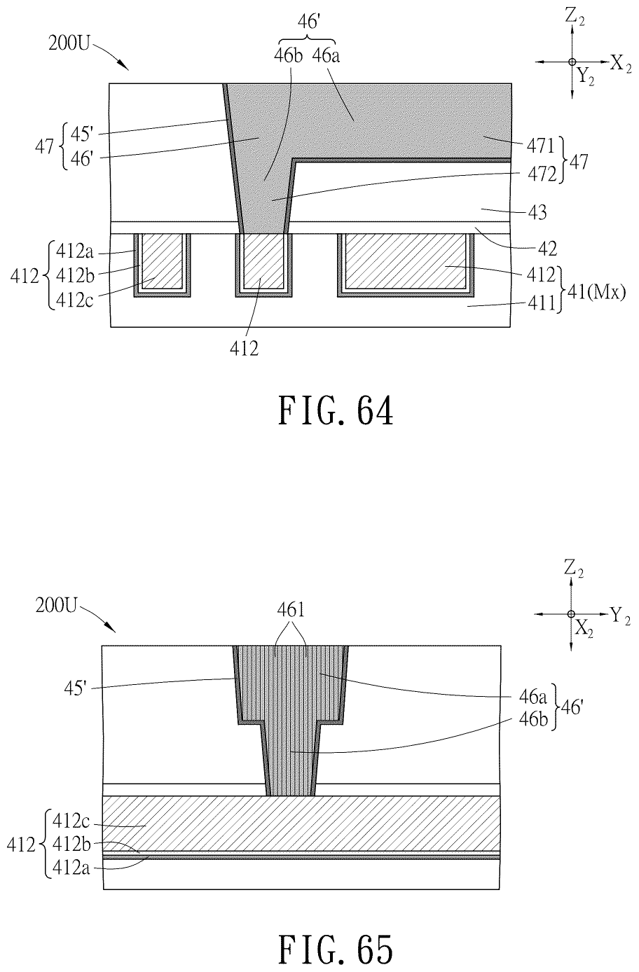

Referring to the examples illustrated in FIGS. 64 and 65, a semiconductor device 200U shown in FIGS. 64 and 65 has a configuration similar to that of the semiconductor device 200T shown in FIGS. 62 and 63, except that in the semiconductor device 200U, the conductive bulk region 46′ of the at least one of the conductive interconnects 47 is in contact with the conductive bulk region 412c of a corresponding one of the conductive interconnects 412 and the barrier layer 45′ of the at least one of the conductive interconnects 47 is not formed between the conductive bulk region 46′ and the conductive bulk region 412c of the corresponding one of the conductive interconnects 412.

An interconnect structure of this disclosure includes a plurality of interconnect layers stacking over one another on a semiconductor substrate. A conductive interconnect serving as a contact via or conductive interconnects serving as metal lines of at least one of the interconnect layers includes a plurality of anisotropic transport material films, which extend in a lengthwise direction of the conductive interconnects when the conductive interconnects serve as the metal lines, or which extend in a heightwise direction when the conductive interconnect serves as the contact via. Therefore, resistance between the at least one of the interconnect layers and an adjacent one of the interconnect layers disposed below or above the at least one of the interconnect layers can be reduced.

In accordance with some embodiments of the present disclosure, a semiconductor device includes a substrate, and an interconnect structure disposed over the substrate. The interconnect structure includes a first conductive interconnect serving as a contact via, and a second conductive interconnect connected to the first conductive interconnect and serving a metal line. The second conductive interconnect includes a plurality of anisotropic transport material films extending in a lengthwise direction of the second conductive interconnect.

In accordance with some embodiments of the present disclosure, the first conductive interconnect is laterally connected to the second conductive interconnect.

In accordance with some embodiments of the present disclosure, each of the anisotropic transport material films has a U-shaped configuration in a cross-section of the second conductive interconnect taken in a direction transverse to the lengthwise direction.

In accordance with some embodiments of the present disclosure, each of the anisotropic transport material films includes a two-dimensional metallic delafossite compound, a MAX-phase composition, a MXene composition, a metal alloy or an intermetallic compound possessing an anisotropic crystal structure, graphene, or combinations thereof.

In accordance with some embodiments of the present disclosure, the two-dimensional metallic delafossite compound has a formula of ABO₂, wherein A and B are different from each other, and each of A and B is palladium, platinum, cobalt, chromium, or rhodium.

In accordance with some embodiments of the present disclosure, the MAX-phase composition has a formula of Mₙ₊₁AXₙ, wherein M is an early transition metal; A is an element in column IIIA or IVA of a periodic table; X is carbon or nitrogen; and n is an integer ranging from about 1 to about 4.

In accordance with some embodiments of the present disclosure, Mis scandium, titanium, vanadium, chromium, zirconium, niobium, molybdenum, hafnium, or tantalum; and A is zinc, cadmium, aluminum, gallium, indium, titanium, silicon, germanium, tin, lead, phosphorus, arsenic, or sulfur.

In accordance with some embodiments of the present disclosure, the MXene composition is a two-dimensional transition metal carbide or nitride having a formula of Mₙ₊₁XₙTₓ, wherein M is scandium, titanium, vanadium, chromium, manganese, yttrium, zirconium, niobium, molybdenum, hafnium, tantalum, or tungsten; X is carbon or nitride; Tₓ is a surface termination selected from a hydrogen radical, an oxygen radical, a hydroxyl radical, a chlorine radical, a fluorine radical, a bromine radical, an iodine radical, a sulfur radical, a selenium radical, a tellurium radical, or combinations thereof; and n is an integer ranging from about 1 to about 4.

In accordance with some embodiments of the present disclosure, the metal alloy or the intermetallic compound includes two or more selected from transition metals or semi-metals.

In accordance with some embodiments of the present disclosure, the metal alloy or the intermetallic compound includes two or more selected from scandium, titanium, vanadium, chromium, manganese, iron, cobalt, copper, zinc, yttrium, zirconium, niobium, molybdenum, technetium, ruthenium, rhodium, palladium, silver, hafnium, tantalum, tungsten, rhenium, osmium, iridium, platinum, gold, aluminum, gallium, indium, germanium, tin, lead, arsenic, antimony, bismuth, selenium, or tellurium.

In accordance with some embodiments of the present disclosure, a semiconductor device includes a substrate, and an interconnect structure disposed over the substrate. The interconnect structure includes a first conductive interconnect serving as a contact via, and a second conductive interconnect connected to the first conductive interconnect and serving a metal line. The first conductive interconnect includes a first conductive bulk region. The second conductive interconnect includes a second conductive bulk region. The first conductive bulk region includes a plurality of first anisotropic transport material films extending in a heightwise direction of the first conductive interconnect, or the second conductive bulk region includes the plurality of first anisotropic transport material films extending in a lengthwise direction of the second conductive interconnect.

In accordance with some embodiments of the present disclosure, the first conductive bulk region includes the plurality of first anisotropic transport material films extending in the heightwise direction of the first conductive interconnect, and each of the plurality of first anisotropic transport material films has a circular configuration in a cross-section of the first conductive interconnect taken in a direction transverse to the heightwise direction.

In accordance with some embodiments of the present disclosure, the first conductive interconnect further includes a barrier layer laterally covering the first conductive bulk region.

In accordance with some embodiments of the present disclosure, the first conductive bulk region includes the plurality of first anisotropic transport material films extending in the heightwise direction of the first conductive interconnect. The second conductive bulk region includes a plurality of second anisotropic transport material films extending in the lengthwise direction of the second conductive interconnect. The lengthwise direction is transverse to the heightwise direction.

In accordance with some embodiments of the present disclosure, the plurality of second anisotropic transport material films are integrated with the plurality of first anisotropic transport material films.

In accordance with some embodiments of the present disclosure, a method for manufacturing a semiconductor device includes: forming a first conductive interconnect over a substrate, the first conductive interconnect serving a contact via and including a first conductive bulk region; and forming a second conductive interconnect connected to the first conductive interconnect, the second conductive interconnect serving as a metal line and including a second conductive bulk region, at least one of the first conductive bulk region and the second conductive bulk region being formed from a plurality of first anisotropic transport material films.

In accordance with some embodiments of the present disclosure, the first conductive bulk region is formed from the plurality of first anisotropic transport material films extending in a heightwise direction of the first conductive interconnect.

In accordance with some embodiments of the present disclosure, the second conductive bulk region is formed from the plurality of first anisotropic transport material films extending in a lengthwise direction of the second conductive interconnect.

In accordance with some embodiments of the present disclosure, the first conductive bulk region is formed from the plurality of first anisotropic transport material films extending in a heightwise direction of the first conductive interconnect. The second conductive bulk region is formed from a plurality of second anisotropic transport material films extending in a lengthwise direction of the second conductive interconnect. The lengthwise direction of the second conductive interconnect is transverse to the heightwise direction of the first conductive interconnect.

In accordance with some embodiments of the present disclosure, each of the plurality of anisotropic transport material films is formed from a two-dimensional metallic delafossite compound, a MAX-phase composition, a MXene composition, a metal alloy or an intermetallic compound possessing an anisotropic crystal structure, graphene, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
an interconnect structure disposed over the substrate, and including:
a first conductive interconnect serving as a contact via, and
a second conductive interconnect connected to the first conductive interconnect and serving a metal line, the second conductive interconnect including a plurality of anisotropic transport material films extending in a lengthwise direction of the second conductive interconnect.

2. The semiconductor device as claimed in claim 1, wherein the first conductive interconnect is laterally connected to the second conductive interconnect.

3. The semiconductor device as claimed in claim 1, wherein each of the plurality of anisotropic transport material films has a U-shaped configuration in a cross-section of the second conductive interconnect taken in a direction transverse to the lengthwise direction.

4. The semiconductor device as claimed in claim 1, wherein each of the plurality of anisotropic transport material films includes a two-dimensional metallic delafossite compound, a MAX-phase composition, a MXene composition, a metal alloy or an intermetallic compound possessing an anisotropic crystal structure, graphene, or combinations thereof.

5. The semiconductor device as claimed in claim 4, wherein the two-dimensional metallic delafossite compound has a formula of ABO₂, wherein A and B are different from each other, and each of A and B is palladium, platinum, cobalt, chromium, or rhodium.

6. The semiconductor device as claimed in claim 4, wherein the MAX-phase composition has a formula of Mₙ₊₁AXₙ, wherein M is an early transition metal; A is an element in column IIIA or IVA of a periodic table; X is carbon or nitrogen; and n is an integer ranging from 1 to 4.

7. The semiconductor device as claimed in claim 6, wherein M is scandium, titanium, vanadium, chromium, zirconium, niobium, molybdenum, hafnium, or tantalum; and A is zinc, cadmium, aluminum, gallium, indium, titanium, silicon, germanium, tin, lead, phosphorus, arsenic, or sulfur.

8. The semiconductor device as claimed in claim 4, wherein the MXene composition is a two-dimensional transition metal carbide or nitride having a formula of Mₙ₊₁XₙTₓ, wherein M is scandium, titanium, vanadium, chromium, manganese, yttrium, zirconium, niobium, molybdenum, hafnium, tantalum, or tungsten; X is carbon or nitride; Tₓ is a surface termination selected from a hydrogen radical, an oxygen radical, a hydroxyl radical, a chlorine radical, a fluorine radical, a bromine radical, an iodine radical, a sulfur radical, a selenium radical, a tellurium radical, or combinations thereof; and n is an integer ranging from 1 to 4.

9. The semiconductor device as claimed in claim 4, wherein the metal alloy or the intermetallic compound includes two or more selected from transition metals or semi-metals.

10. The semiconductor device as claimed in claim 9, wherein the metal alloy or the intermetallic compound includes two or more selected from scandium, titanium, vanadium, chromium, manganese, iron, cobalt, copper, zinc, yttrium, zirconium, niobium, molybdenum, technetium, ruthenium, rhodium, palladium, silver, hafnium, tantalum, tungsten, rhenium, osmium, iridium, platinum, gold, aluminum, gallium, indium, germanium, tin, lead, arsenic, antimony, bismuth, selenium, or tellurium.

11. A semiconductor device, comprising:
a substrate; and
an interconnect structure disposed over the substrate, and including:
a first conductive interconnect serving as a contact via, the first conductive interconnect including a first conductive bulk region, and
a second conductive interconnect connected to the first conductive interconnect and serving as a metal line, the second conductive interconnect including a second conductive bulk region,
wherein the first conductive bulk region includes a plurality of first anisotropic transport material films extending in a heightwise direction of the first conductive interconnect, or the second conductive bulk region includes the plurality of first anisotropic transport material films extending in a lengthwise direction of the second conductive interconnect.

12. The semiconductor device as claimed in claim 11, wherein the first conductive bulk region includes the plurality of first anisotropic transport material films extending in the heightwise direction of the first conductive interconnect, and each of the plurality of first anisotropic transport material films has a circular configuration in a cross-section of the first conductive interconnect taken in a direction transverse to the heightwise direction.

13. The semiconductor device as claimed in claim 11, wherein the first conductive interconnect further includes a barrier layer laterally covering the first conductive bulk region.

14. The semiconductor device as claimed in claim 11, wherein
the first conductive bulk region includes the plurality of first anisotropic transport material films extending in the heightwise direction of the first conductive interconnect; and
the second conductive bulk region includes a plurality of second anisotropic transport material films extending in the lengthwise direction of the second conductive interconnect, the lengthwise direction being transverse to the heightwise direction.

15. The semiconductor device as claimed in claim 14, wherein the plurality of second anisotropic transport material films are integrated with the plurality of first anisotropic transport material films.

16. A method for manufacturing a semiconductor device, comprising:
forming a first conductive interconnect over a substrate, the first conductive interconnect serving a contact via and including a first conductive bulk region; and
forming a second conductive interconnect connected to the first conductive interconnect, the second conductive interconnect serving as a metal line and including a second conductive bulk region, at least one of the first conductive bulk region and the second conductive bulk region being formed from a plurality of first anisotropic transport material films.

17. The method as claimed in claim 16, wherein the first conductive bulk region is formed from the plurality of first anisotropic transport material films extending in a heightwise direction of the first conductive interconnect.

18. The method as claimed in claim 16, wherein the second conductive bulk region is formed from the plurality of first anisotropic transport material films extending in a lengthwise direction of the second conductive interconnect.

19. The method as claimed in claim 16, wherein
the first conductive bulk region is formed from the plurality of first anisotropic transport material films extending in a heightwise direction of the first conductive interconnect, and
the second conductive bulk region is formed from a plurality of second anisotropic transport material films extending in a lengthwise direction of the second conductive interconnect, the lengthwise direction of the second conductive interconnect being transverse to the heightwise direction of the first conductive interconnect.

20. The method as claimed in claim 16, wherein each of the plurality of anisotropic transport material films is formed from a two-dimensional metallic delafossite compound, a MAX-phase composition, a MXene composition, a metal alloy or an intermetallic compound possessing an anisotropic crystal structure, graphene, or combinations thereof.
